(19) United States
(12) Patent Application Publication
(10) Pub. No.: US 2007/0096332 A1
(43) Pub. Date: May 3, 2007

(54) Electronic component, module, module assembling method, module identification method and module environment setting method

(76) Inventors: Tomotoshi Satoh, Yamatokoriyama-shi (JP); Yoshihiko Nemoto, Chiyoda-ku (JP); Kenji Takahashi, Tsukuba-shi (JP); Yukiharu Akiyama, Kodaira-shi (JP)

Correspondence Address: NIXON & VANDERHYE, PC, 901 NORTH GLEBE ROAD, 11TH FLOOR, ARLINGTON, VA, 22203, US

(21) Appl. No.: 10/558,269

(22) PCT Filed: May 28, 2004
(86) PCT No.: PCT/JP04/07377

§ 371 Date: Oct. 12, 2006

(30) Foreign Application Priority Data
May 28, 2003 (JP) 2003-150834

(51) Int. Cl. H01L 23/52

(52) U.S. Cl. 257/777

(57) ABSTRACT

An electronic component capable of being assembled into a module in the form of a stack of a plurality of layers is provided. Terminals of terminal groups (31 to 36) are formed so as to have rotational symmetry of a predetermined fold-number or have rotational symmetry and symmetry with respect to the plane containing a symmetric axis line. The terminals (A0 to A7, RFCG) of common connection terminal groups (32, 36) have connecting portions formed on the both surfaces in a stacking direction. Among the terminals of individual connection terminal groups (31, 33), a specific terminal CS; KEY has a connection portion formed at least on one of the both surfaces in the stacking direction while the remaining associated terminals NC; DMY have connection portions formed on the both surfaces in the stacking direction. When such electronic components (20) are stacked so as to be shifted from each other by the angle obtained by dividing 360 degrees by the predetermined fold-number or in addition in the inverted state, it is possible to assemble a module using the electronic components (20) having the same configuration.

### TECHNICAL FIELD

The present invention relates to an electronic component, a module assembled by stacking a plurality of the electronic components, a method of assembling the module, a method of identifying the assembled module, and a method of setting an operation environment of the assembled module.

### BACKGROUND ART

FIG. 23 is a perspective view showing a first conventional art module 1. In order to realize high-density packaging of large-scale integrated circuits (LSIs) 2, the module 1 is formed by stacking the LSIs 2. The LSI 2 is mounted on a tape carrier 3 to configure a tape carrier package (TCP) 4, and the TCPs 4 are stacked to form the module 1. This module 1 is configured so that the LSIs 2 can be identified on the basis of the configurations of the tape carriers 3.

Each of the LSIs 2 has a chip-side selection terminal 5 for inputting information for selecting and specifying the LSI, and a chip-side general terminal 6 for inputting and outputting information relating to a processing operation that should be executed, and the module is configured so that, from a circuit board (not shown), a command of a processing operation is given to the chip-side general terminal 6 and information for specifying the LSI 2 that executes the processing operation is given to the chip-side selection terminal 5, and the specified LSI 2 executes the processing operation.

The chip-side selection terminals 5 of the LSIs 2 are individually connected via wires 7 formed on the tape carriers 3 to board-side selection terminals 8 formed on the circuit board. Moreover, the chip-side general terminals 6 of the LSIs 2 are commonly connected via wires 9 formed on the tape carriers 3 to board-side general terminals 10 formed on the circuit board. In order to individually connect the chip-side selection terminals 5 to the board-side selection terminals 8, the same number of board-side selection terminals 8a to 8c (denoted by reference numeral 8 when generically named) as the number of the LSIs are formed on the circuit board, the wires 7 are formed into redundant patterns having wire portions that can be connected to all of the board-side selection terminals 8a to 8c, and by leaving only necessary wire portions and cutting and removing unnecessary portions, the chip-side selection terminals 5 are individually connected to one of the board-side selection terminals 8a to 8c. Thus, it is possible to individually specify the LSIs 2 from the circuit board (for example, refer to Japanese Unexamined Patent Publication JP-A 2-290048 (1990)).

FIG. 24 is a perspective view showing the connection structure between a board and a bottom chip in a second conventional art. FIG. 25 is a perspective view showing the connection structure between the board and a middle chip in the second conventional art. FIG. 26 is a perspective view showing the connection structure between the board and a top chip in the second conventional art module. In FIGS. 24 to 26, in order to make it easy to understand, only terminals formed so as to pierce through the LSIs and wires between the terminals and circuits inside the LSIs are illustrated, and other components in the LSIs, for example, interlayer insulating films and so on are not illustrated.

There is a problem such that the performance of the LSI cannot be sufficiently delivered because of a signal delay by the tape carrier 3 in the case of using the TCP as in the first conventional art and, as the second conventional art that can solve the problem and make the LSI become high-speed and have a high level of function, a technique of forming a module by providing the LSI with a terminal that pierces therethrough from the front to the back and stacking in the wafer state or in the chip state without using the tape carrier is known. Also in the second conventional art, the module should be configured so that it is possible to specify each of the stacked LSIs from the circuit board as in the first conventional art.

The LSIs are provided with contact portions 14 corresponding to the chip-side connection terminals connected to an internal circuit. The LSIs are provided with the same number of connection terminals 15a to 15c as the number of the LSIs, which pierce through the LSIs in the thickness direction. The connection terminals 15a to 15c are terminals for individually connecting the LSIs to the circuit board, and connected to the same number of board-side connection terminals as the number of the LSIs, which are formed on the circuit board. The contact portions 14 of the LSIs are connected to the mutually different connection terminals 15a to 15c via wires 16a to 16c disposed to the LSIs, whereby the contact portions 14 of the LSIs are individually connected to board-side selection terminals.

Further, in a third conventional art, a technique of stacking a plurality of segments is known. In this technique, terminals of the segments are electrically connected to each other by using an electrically conductive adhesive, and the segments are mechanically connected (for example, refer to Japanese Unexamined Patent Publication based on International Application JP-A 2001-514449).

Furthermore, in a fourth conventional art module, a stacking structure of memory chips onto a logic device, which is used as a technique of reducing a capacity load on integrated chips that are stacked with protective diodes detached, is known. In the fourth prior art, two stacking structures are utilized, and the first stacking structure has a configuration such that a terminal for specifying the memory chip is different in each stage, that is, in each of the memory chips, and configured so that it is possible to control the memory chips. In the second stacking structure, the memory chips are stacked in the shifted state along one edges of the memory chips in a direction perpendicular to the thickness direction (for example, refer to U.S. Pat. No. 6,141,245).

Although the second prior art can solve the problem of the first prior art, it is necessary to dispose the wires 16a to 16c individually connecting the contact portions 14 and the connection terminals 15a to 15c as described above because the LSIs are located and stacked in the same attitude. Since these wires 16a to 16c must be formed on the LSIs, the chips have different configurations. Therefore, it is necessary to produce as different chips in the manufacturing process.

There is no problem in the case of stacking different kinds of chips because the chips have different configurations originally, but, for example, in the case of realizing a large-capacity memory by stacking a large number of memory chips, it is necessary to produce the same number of chips having different configurations as the number of stacked chips as different chips as described above because the chips are stacked though the memory chips may have the same configuration when not stacked, with the result that considerably excessive time and effort are required.

Such a problem cannot be solved by the first prior art, the third prior art, or the first stacking structure of the fourth prior art.

Further, in the second stacking structure of the fourth prior art, the memory chips may be formed into the same shape, but the terminals arranged on the edges (at least two sides) extending in a direction in which the memory chips are shifted can be used merely as terminals for specifying the memory chips, and terminals for connecting a bus with the memory chips, that is, connecting in common must be disposed by using an edge (two sides at the maximum) extending in a different direction from the direction in which the memory chips are shifted. Therefore, a bus width is constrained by the limitation of the number of terminals that can be disposed.

### DISCLOSURE OF INVENTION

An object of the invention is to provide an electronic component capable of being assembled into a module in the form of a stack of a plurality of layers, having less constraints with respect to bus width, a module using the electronic components, and a module assembling method, a module identification method and a module environment setting method.

The invention is an electronic component having an internal circuit, capable of being assembled into a module in the form of a stack of a plurality of layers, comprising:

a common connection terminal group; and

an individual connection terminal group,

wherein the common connection terminal group is located so as to have rotational symmetry of a predetermined fold-number, and the common connection terminal group has a plurality of terminals which are connected to the internal circuit, and terminals which are to be connected to a component outside the module in common with terminals of the other electronic components of the stack, and connecting portions for connecting with the terminals of the common connection terminal groups of the other electronic components are formed on both surfaces in the stacking direction of the electronic components, and

wherein the individual connection terminal group is located so as to have rotational symmetry of the predetermined fold-number, and has a plurality of terminals including at least one specific terminal and related terminals, which specific terminal is connected to the internal circuit and is to be connected to a component outside the module independent from the specific terminals of the other electronic components of the stack, and has a connecting portion for connecting with the terminals of the individual connection terminal groups of the other electronic components of the stack, formed on at least one surface of the surfaces in the stacking direction of the electronic component, and which related terminals are disposed in relation to the specific terminals of the other electronic components of the stack, and have connecting portions for connecting with the terminals of the individual connection terminal groups of the other electronic components, formed on both surfaces in the stacking direction of the electronic component.

According to the invention, the terminals of the common connection terminal group are formed so as to have rotational symmetry of a predetermined fold-number, and have connecting portions formed on both surfaces in the stacking direction of the electronic components. Moreover, the terminals of the individual connection terminal group are formed so as to have rotational symmetry through the predetermined fold-number, at least one of the terminals, namely, the specific terminal is provided with the connecting portion formed on at least one surface of the surfaces in the stacking direction of the electronic component, and the rest of the terminals, namely, the related terminals are provided with the connecting portions formed on both surfaces in the stacking direction of the electronic component.

The electronic components with the terminals formed in a symmetric location in this manner, when stacked so as to be shifted from each other by an angle obtained by dividing 360 degrees by the predetermined fold-number, make it possible to assemble a module in which the terminals of the common electrode terminal groups are commonly connected to the component outside the module and the specific terminals of the individual connection terminal groups are individually connected to the component outside the module. Consequently, on assembling a module by stacking a plurality of electronic components, it is possible to use electronic components having the same configuration, without preparing electronic components having different configurations. Accordingly, it is possible to reduce time and effort to manufacture electronic components for assembling a module by stacking, and easily manufacture the electronic components.

Furthermore, the number of the common connection terminals is not limited, and it is possible to make the constraints with respect to a so-called bus width, namely, the amount of data that can be transmitted per unit time by using the common connection terminals as little as possible. Besides, it is possible to make the module have a small size such that the external size when the module is projected on a surface perpendicular to the stacking direction is almost the same as the external sizes of the electronic components.

Further, the invention is characterized in that, on stacking the plurality of electronic components, the electronic components are stacked so that one surfaces of the respective electronic components are all directed to one direction.

According to the invention, it is possible to easily form a module in which the number of layers of the electronic components is equal to or less than the predetermined fold-number.

Furthermore, the invention is characterized in that:

the terminals of the common electrode terminal groups and the individual connection terminal groups are located so as to have not only rotational symmetry of the predetermined fold-number but also line symmetry with respect to a symmetry line that passes through a center of rotation symmetry, and

on stacking the plurality of electronic components, at least one of the electronic components is stacked so that one surface of the at least one electronic component is directed to one direction, and the remaining electronic components are stacked so that the other surfaces of the respective electronic components are directed to the one direction.

According to the invention, the terminals of the common electrode terminal groups and the individual connection terminal groups have line symmetry with respect to a symmetry line that passes through the center of rotation symmetry, it is also possible to stack the electronic components in the inverted state with respect to the stacking direction, and it is possible even in this state of assembling a module in which the terminals of the common electrode terminal groups are commonly connected to the component outside the module and the specific terminals of the individual connection terminal groups are individually connected to the component outside the module. Accordingly, it is possible to easily form a module in which the number of layers is two or less times the predetermined fold-number.

Still further, the invention is characterized in that, on stacking the plurality of electronic components, principal surfaces of two of the electronic components are opposed to each other, and the plurality of opposed electronic component pairs are stacked further.

According to the invention, by stacking the electronic component pairs formed so that the principal surfaces of the two electronic components are opposed, namely, the one surfaces in the stacking direction are opposed to each other, in the shifted state from each other by an angle obtained by dividing 360 degrees by the predetermined fold-number, it is possible to easily form a module in which the number of layers is two or less times the predetermined fold-number.

Still further, the invention is characterized in that the specific terminal has the connecting portion for connecting with the terminals of the individual connection terminal groups of the other electronic components, formed on only one surface of the surfaces in the stacking direction thereof.

According to the invention, the specific terminal is provided with the connecting portion formed on only one surface of the surfaces in the stacking direction of the electronic component, so that it is possible to reduce a portion connected to the component outside the module. Consequently, it is possible to reduce a load on the module on driving the module from the component outside the module, and it is possible to contribute to making the module become high-speed and have a high level of function.

Still further, the invention is characterized in that the external shape is a regular polygon that has the same number of angles as that of the predetermined fold-number.

According to the invention, the external shape is a regular polygon that has the same number of angles as that of the predetermined fold-number, so that in the case of stacking the electronic components, it is possible to stack them with the rim portions lined up. Consequently, it is possible to make an occupied space necessary to locate the module as small as possible.

Still further, the invention is characterized in that the individual connection terminal groups include an attitude information output terminal group in which the specific terminal is connected to an internal circuit that outputs information representing valid in response to an output request from the component outside the module, and the related terminals are connected to an internal circuit that, in response to an output request from the component outside the module, is switched between a state of outputting information representing invalid that takes priority to information representing valid in the component outside the module, and a state of noninterfering with the related terminals.

According to the invention, the attitude information output terminal group is provided as one of the individual connection terminal groups, and by outputting information representing valid from the specific terminals in response to an output request from the component outside the module to the terminals while switching the related terminals of the attitude information output terminal groups, it is possible to give information on the positions of the specific terminals of the electronic components to the component outside the module. Consequently, it is possible to give information representing the attitudes of the electronic components to the component outside the module.

Still further, the invention is characterized in that:

each of the electronic components has an internal circuit that sets an operation environment appropriate to a stacking state of each of the electronic components based on a setting command given from the component outside the module, and

the common connection terminal groups include a command input terminal group provided with command input terminals to which a setting command as a command for setting an operation environment appropriate to a stacking state in each of the electronic components is given from the component outside the module.

According to the invention, the internal circuit that sets an operation environment appropriate to a stacking state is provided, and the command input terminal group is provided as one of the common connection terminal groups. When a setting command is given from the component outside the module to the command input terminal group, an operation environment appropriate to a stacking state is set by the internal circuit. Consequently, it is possible to give a setting command and set an operation environment after stacking the plurality of electronic components and forming the module, and it is possible to assemble a highly convenient module that operates in a favorable manner.

Still further, the invention is characterized in that alignment marks used for positioning on stacking the electronic components are located so as to have the same symmetry as that of the terminals.

According to the invention, the alignment marks used for positioning on stacking the electronic components are located so as to have the symmetry. Consequently, as far as the component outside the module has at least one alignment mark, it is possible to position the electronic components in positions shifted from each other by an angle obtained by dividing 360 degrees by the predetermined fold-number.

Still further, the invention is characterized in that the electronic component is a semiconductor device in which the internal circuit is formed on at least one principal surface of a semiconductor substrate, and the terminals of the common connection terminal groups and the individual connection terminal groups are formed by conductive paths that reach an opposite surface from the principal surface.

According to the invention, it is possible to obtain a favorable module by stacking the plurality of semiconductor devices.

Still further, the invention is a module formed with the plurality of electronic components stacked.

According to the invention, by stacking the plurality of electronic components having the same configuration, a module is formed, and it is possible to easily obtain a favorable module.

Still further, the invention is a method of assembling a module by stacking the plurality of electronic components, comprising:

stacking the electronic components so that attitudes thereof are shifted from each other by an angle obtained by dividing 360 degrees by the predetermined fold-number about the center of rotational symmetry; and

connecting the connecting portions of the terminals of the electronic components adjacent to each other in the stacking direction, to each other.

According to the invention, the plurality of electronic components are stacked so that the attitudes thereof are shifted from each other by an angle obtained by dividing 360 degrees by the predetermined fold-number about the center of rotational symmetry, and the connecting portions of the terminals of the electronic components adjacent to each other in the stacking direction are connected to each other. Consequently, it is possible to assemble a module in which the terminals of the common electrode terminal groups are commonly connected to the component outside the module and the specific terminals of the individual connection terminal groups are individually connected to the component outside the module. Such a module that allows high-density packaging can be assembled with ease.

Still further, the invention is a method of assembling a module by stacking the plurality of electronic components on a board, comprising:

stacking the electronic components so that attitudes thereof are shifted from each other by an angle obtained by dividing 360 degrees by the predetermined fold-number about the center of rotational symmetry based on positional relation between an alignment mark formed on the board and the alignment marks formed on the electronic components; and

connecting the connecting portions of the terminals of the electronic components adjacent to each other in the stacking direction, to each other.

According to the invention, the plurality of electronic components are stacked so that the attitudes thereof are shifted from each other by an angle obtained by dividing 360 degrees by the predetermined fold-number about the center of rotational symmetry, and the connecting portions of the terminals of the electronic components adjacent to each other in the stacking direction are connected to each other. Consequently, it is possible to assemble a module in which the terminals of the common electrode terminal groups are commonly connected to the component outside the module and the specific terminals of the individual connection terminal groups are individually connected to the component outside the module. Such a module that allows high-density packaging can be assembled with ease.

Furthermore, the alignment marks having the same symmetry as that of the terminals are formed on the electronic component, and it is possible to position the electronic components by using the alignment mark formed on the board. On this positioning, at least one alignment mark on the board is sufficient. The electronic component is formed more accurately than the board, and as to the alignment marks, the alignment marks on the electronic component are also formed more accurately than the alignment mark on the board. By forming the alignment marks on the electronic component so as to have symmetry as described before, it is possible to position the electronic components by using the highly accurate alignment marks on the electronic component as much as possible, and it is possible to position the electronic components with high accuracy, so that it is possible to assemble a highly accurate module.

Still further, the invention is characterized in that the electronic component is a semiconductor device in which an internal circuit is formed on at least one principal surface of a semiconductor substrate, and the terminals of the common connection terminal groups and the individual connection terminal groups are formed by conductive paths that reach an opposite surface from the principal surface.

According to the invention, it is possible to assemble a favorable module by stacking the plurality of semiconductor devices.

Still further, the invention is a method of identifying a module assembled by stacking the plurality of electronic components so that attitudes thereof are shifted from each other by an angle obtained by dividing 360 degrees by the predetermined fold-number about the center of rotational symmetry and connecting the connecting portions of the terminals of the electronic components adjacent to each other in the stacking direction, to each other, comprising:

by giving an output request to the terminals of the attitude information terminal groups of the electronic components, based on outputted information representing valid and information representing invalid, detecting the positions of the specific terminals of the attitude information terminal groups in the electronic components and detecting attitudes of the electronic components, and identifying a module based on stacking states of the electronic components.

According to the invention, an output request is given to the terminals of the attitude information terminal groups of a module assembled by stacking the plurality of electronic components having the attitude information terminal groups. Consequently, it is possible to obtain information representing valid from the specific terminals of the attitude information terminal groups of the electronic components, and it is possible to detect the positions of the specific terminals. Consequently, it is possible to detect the attitudes of the electronic components in the module, and it is possible to detect the alignment of the electronic components in the module. Accordingly, it is possible to identify modules on the basis of differences of the alignments.

Still further, the invention is characterized in that the electronic component is a semiconductor device in which an internal circuit is formed on at least one principal surface of a semiconductor substrate, and the terminals of the common connection terminal groups and the individual connection terminal groups are formed by conductive paths that reach the opposite surface from the principal surface.

According to the invention, it is possible to favorably identify a module assembled by stacking the plurality of semiconductor devices.

Still further, the invention is a method of setting an operation environment of a module assembled by stacking the plurality of electronic components so that attitudes thereof are shifted from each other by an angle obtained by dividing 360 degrees by the predetermined fold-number about the center of rotational symmetry and connecting the connecting portions of the terminals of the electronic components adjacent to each other in the stacking direction, to each other, comprising:

giving a setting command to the command input terminal groups and setting operation environments appropriate to stacking states in the electronic components.

According to the invention, a setting command is given to the terminals of the command input terminal groups of a module assembled by stacking the plurality of electronic components having the command input terminal groups. When a setting command is given to the electronic components, operation environments are set in response to the setting command. Consequently, it is possible to set operation environments in the electronic components.

Still further, the invention is characterized in that the electronic component is a semiconductor device in which an internal circuit is formed on at least one principal surface of a semiconductor substrate, and the terminals of the common connection terminal groups and the individual connection terminal groups are formed by conductive paths that reach an opposite surface from the principal surface.

According to the invention, it is possible to set operation environments in the semiconductor devices of a module assembled by stacking the plurality of semiconductor devices, and it is possible to obtain a favorable module.

### BRIEF DESCRIPTION OF DRAWINGS

Other and further objects, features, and advantages of the invention will be more explicit from the following detailed description taken with reference to the drawings wherein:

FIG. 1 is a front view showing a memory chip 20 according to an embodiment of the invention;

FIG. 2 is a perspective view showing a memory module 21 assembled by using the memory chips 20;

FIG. 3 is a cross section view schematically showing an example of the connection state of the terminals between the adjacent chips 20;

FIG. 4 is a cross section view schematically showing another example of the connection state of the terminals between the adjacent chips 20;

FIG. 5 is a view for explaining a method of setting an operation environment in the chip 20;

FIG. 6 is a circuit view showing a circuit 50 for setting an operation environment in the chip 20;

FIGS. 7A to 7E are cross section views showing an example of a process of forming a terminal;

FIG. 8 is a front view of the chip 20 for explaining the location of alignment marks 60a to 60h;

FIGS. 9A to 9C are views for explaining a method of stacking the chips 20 by using the alignment marks 60a to 60h;

FIG. 10 is a front view showing a chip 120 according to another embodiment of the invention;

FIG. 11 is a perspective view showing a module 121 assembled by stacking the chips 120;

FIG. 12 is a front view showing a chip 220 according to still another embodiment of the invention;

FIG. 13 is a front view showing a chip 320 according to still another embodiment of the invention;

FIG. 14 is a perspective view showing a module 321 assembled by stacking the chips 320;

FIG. 15 is a cross section view schematically showing an example of the connection state of the terminals between the adjacent chips 320;

FIG. 16 is a cross section view schematically showing another example of the connection state of the terminals between the adjacent chips 320;

FIG. 17 is a cross section view schematically showing another example of the connection state of the terminals between the adjacent chips 320;

FIG. 18 is a front view of the chip 320 for explaining the location of alignment marks 360a to 360d;

FIG. 19 is a view for explaining a method of stacking the chips 20 by using the alignment marks 360a to 360d;

FIG. 20 is a front view showing a chip 420 according to still another embodiment of the invention;

FIG. 21 is a perspective view showing a memory package 520 according to still another embodiment of the invention;

FIG. 22 is a cross section view showing a module with memory packages 550 stacked;

FIG. 23 is a perspective view showing a first conventional art module 1;

FIG. 24 is a perspective view showing the connection structure between a board and a bottom chip in a second prior art;

FIG. 25 is a perspective view showing the connection structure between the board and a middle chip in the second prior art; and

FIG. 26 is a perspective view showing the connection structure between the board and a top chip in the second prior art.

### BEST MODE FOR CARRYING OUT THE INVENTION

Now referring to the drawings, preferred embodiments of the invention are described below.

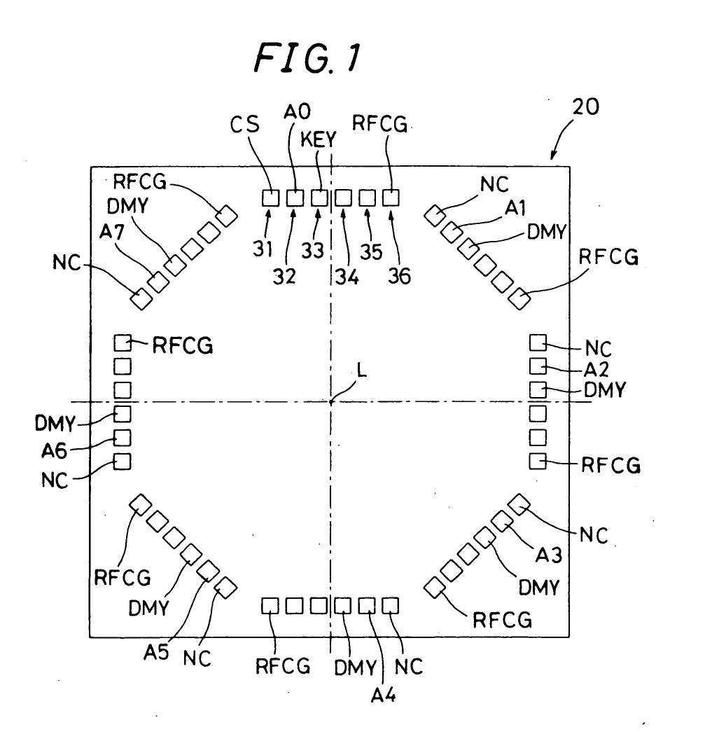

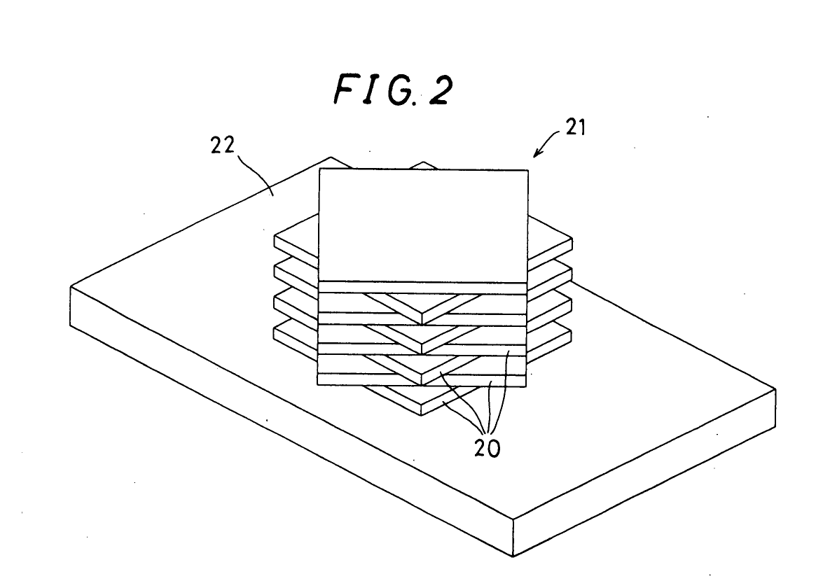

FIG. 1 is a front view showing a memory chip 20 according to an embodiment of the invention. FIG. 2 is a perspective view showing a memory module 21 assembled by using the memory chips 20 in a state mounted on a board 22. The memory chip (occasionally referred to as “chip” hereinafter) 20 is an electronic component, and used for assembling the memory module (occasionally referred to as “module” hereinafter) 21, which is high-capacitance and small-sized, by stacking a plurality of chips 20 in order to realize high-density packaging.

The chip 20 is formed into a plate shape, and the external shape thereof perpendicular to a thickness direction is a square shape. The chip 20 is a semiconductor device, and has a configuration that an internal circuit (not shown) is formed on at least a principal surface that is a one surface in a predetermined thickness direction of a semiconductor substrate. The principal surface of the chip 20 is one surface in the predetermined thickness direction of the semiconductor substrate. Assuming that the thickness direction of the chip 20 is a stacking direction, the plurality of chips 20 are stacked into a plurality of layers on the board 22, and the module 21 is mounted on the board 22. The board 22 is equivalent to the component outside the module. FIG. 1 shows the chip 20 viewed in the thickness direction. The board 22 may be a general circuit board typified by a printed circuit board, or may be a so-called interposer board for converting terminal pitches, as far as the board has terminals connected to terminals of the chips 20 of the module 21.

The chip 20 has a plurality of terminal groups, in the present embodiment, six terminal groups 31 to 36. The terminal groups 31 to 36 have a plurality of terminals, 1y, and the terminals of each of the terminal groups 31 to 36 are located and formed so as to be N-fold symmetric (N is an integer of 2 or more) in positions having rotational symmetry of a predetermined fold-number about a rotational symmetry central axial line (occasionally referred to as “symmetry axial line” hereinafter) L that is parallel to the thickness direction. In the present embodiment, the predetermined fold-number is eight, each of the terminal groups 31 to 36 have terminals of a number that is a natural number multiple of the predetermined fold-number, and the terminals are located in positions having eight-fold rotational symmetry, more specifically, arranged substantially in a perimeter direction about the symmetry axial line L, that is, located in a peripheral arrangement. The symmetry axial line L may be aligned or may not be aligned with the central axial line of the chip 20. The terminals of the terminal groups are formed by conductive paths that reach the opposite surface, which is the other surface in the thickness direction, from the principal surface. The conductive path is made of an electrically conductive material.

The terminal groups 31 to 36 include, for example, the chip specific terminal group 31, the main information input-output terminal group 32, the attitude information output terminal group 33, and the command input terminal group 36. The chip specific terminal group 31 is a terminal group for selectively specifying the chip 20. The main information input-output terminal group 32 is a terminal group for inputting and outputting information stored in the chip 20. The attitude information output terminal group 33 is a terminal group for outputting attitude information of the chip 20. The command input terminal group 36 is a terminal group for inputting a setting command, which is a command for setting an operation environment in the chip 20. The remaining terminal groups 34, 35 may be terminal groups used for another object, for example, may be terminal groups for inputting driving electric power.

The chip specific terminal group 31 has eight terminals, which is one time the predetermined fold-number (the same as the predetermined fold-number), and the eight terminals include one chip specific terminal CS and seven non-connection terminals NC. The chip specific terminal CS is a specific terminal, and connected to the internal circuit (not shown) formed on the chip 20. The non-connection terminals NC are related terminals, and terminals that are not connected to the internal circuit and have the same configuration.

The main information input-output terminal group 32 has eight main information terminals A0 to A7, which is one time the predetermined fold-number. Although the main information terminals A0 to A7 are individually connected to circuits of the internal circuit different from each other, the circuits are circuits, and the main information terminals A0 to A7 are equivalent terminals.

The attitude information output terminal group 33 has eight terminals, which is one time the predetermined fold-number, and the eight terminals include one reference terminal KEY and seven dummy terminals DMY. The reference terminal KEY is a specific terminal, and connected to the internal circuit formed on the chip 20. The dummy terminals DMY are related terminals, and terminals that are commonly connected to the same circuit of the internal circuit and have the same configuration.

The command input terminal group 36 have eight command terminals RFCG, which is one time the predetermined fold-number. The command terminals RFCG are terminals that are commonly connected to the same circuit of the internal circuit and have the same configuration.

The detailed description of the terminals of the remaining terminal groups 34, 35 will be omitted.

The terminal groups 31 to 36 are classified into common connection terminal groups and individual connection terminal groups. The chip specific terminal group 31 and the attitude information output terminal group 33 are the individual connection terminal groups, and the main information input-output terminal group 32 and the command input terminal group 36 are the common connection terminal groups. The remaining terminal groups 34, 35 are classified into either the common connection terminal groups or the individual connection terminal groups on the basis of the configurations thereof. For example, in the case where the terminal group 34 is a terminal group for inputting driving electric power, the terminal group 34 is the common connection terminal group.

The plurality of chips 20 with these terminals formed are stacked so that attitudes thereof are shifted from each other about the axial line L by an angle obtained by dividing 360 degrees by the predetermined fold-number (occasionally referred to as “set angle” hereinafter; 45 degrees obtained by dividing 360 degrees by 8 in the examples of FIGS. 1, 2). Here, a language “to be shifted from each other by the set angle” means that arbitrary two of the plurality of stacked chips 20 are shifted from each other by an angle of a natural number multiple of the set angle, and it is not necessary that the adjacent chips are shifted from each other by the set angle. Therefore, the chips 20 are stacked so that the chips 20 in the same attitude do not exist. Moreover, the stacking number should be equal to or less than the predetermined fold-number, in the present embodiment, eight layers, which is the same number as the predetermined fold-number, and the eight-layer module 21 is configured by using the eight chips 20.

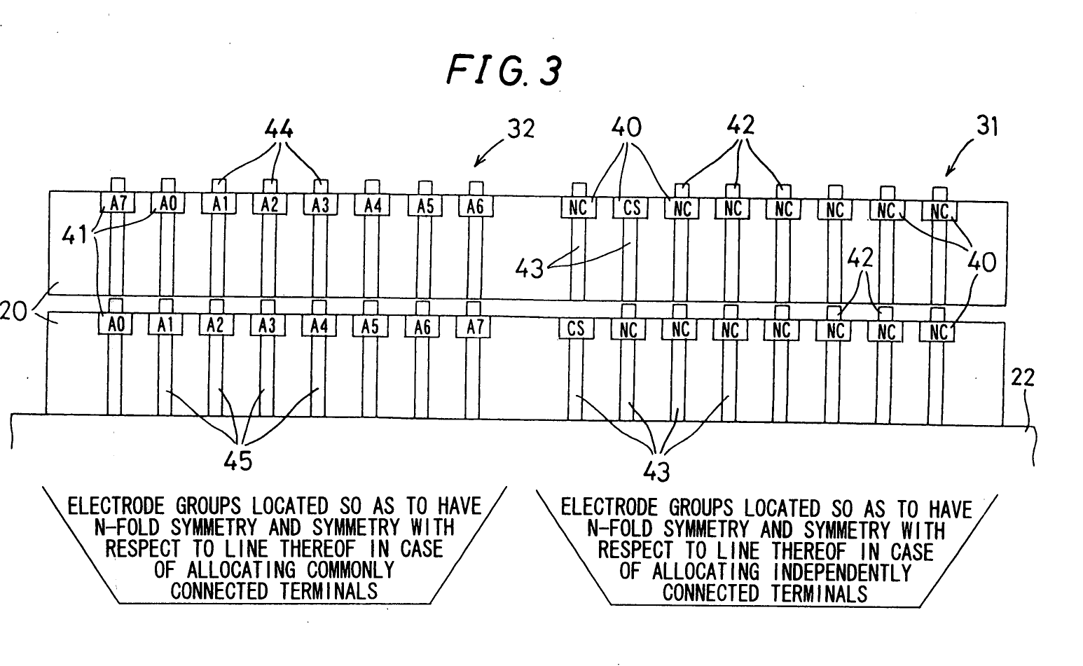

FIG. 3 is a cross section view schematically showing an example of the connection state of the terminals between the adjacent chips 20. FIG. 3 shows two terminal groups of the chip specific terminal group 31 and the main information input-output terminal group 32 as an example. Moreover, in order to make it easy to understand, FIG. 3 shows the two chips by aligning the terminals CS, NC of the chip specific terminal groups 31 on the right side and aligning the terminals A0 to A7 of the main information input-output terminal groups 32 on the left side.

The terminals of the terminal groups 31 to 36 are provided with terminal bases formed on one surface in the thickness direction of the chip 20. On stacking the chips 20, the chips 20 are stacked in a state where the one surfaces in the thickness direction of the chips with the terminal bases formed are directed to one direction, in concrete, in the face-up state in which the terminal bases face a side opposite to the board 22. The terminals CS, NC of the chip specific terminal group 31 and the terminals A0 to A7 of the main information input-output terminal group 32 are also provided with terminal bases 40 and terminal bases 41 formed on the one surfaces in the thickness direction of the chips 20.

The chip specific terminal CS is connected to the base terminal 40, and provided with a connecting portion 43 that pierces through the chip 20 and is formed on the surface on the other side in the thickness direction. The chip specific terminal CS may be provided with or may not be provided with a connecting portion formed on the one surface in the thickness direction of the chip and, in the present embodiment, the connecting portion is not formed. Thus, the chip specific terminal CS is provided with the connecting portion formed only on at least one surface of the surfaces in the thickness direction of the chip, in concrete, only on the surface closer to the board 22. The non-connection terminal NC is connected to the terminal base 40, provided with a bump-like connecting portion 42 that protrudes toward the one surface in the thickness direction of the chip from the terminal base, formed on the one surface in the thickness direction of the chip, and provided with the connecting portion 43 that pierces through the chip 20 and is formed on the other surface in the thickness direction of the chip.

With such a configuration, the chip specific terminal CS of the chip 20 located closest to the board 22 is directly connected to a board-side specific terminal (not shown) for specifying the chip 20 formed on the board 22, and the chip specific terminals CS of the remaining chips 20 are connected to the board-side specific terminal via the non-connection terminals NC of the chips 20 located closer to the board 22. Thus, the chip specific terminals CS are individually connected to the board-side specific terminal. The chip specific terminal group 31 is a terminal group used for specification of the chip 20 by the board 22 and, with the configuration as described above, it is possible to give information for specifying the chips 20 from the board 22.

Further, the chip specific terminal CS does not have a connecting portion with the chip 20 on the opposite side to the board 22. With such a configuration, connection to the board-side specific terminal of the board 22 is limited to the minimum necessary, and a load on the module 21 viewed from the board 22 is reduced, whereby it is possible to realize the favorable module 21 that is capable of smooth processing. Although the chips are stacked in the face-up state in the present embodiment, the chips 20 may be stacked in the face-down state in which the terminal bases face the board 22 in another embodiment of the invention, and in this case, by providing the chip specific terminal CS with only the bump-like connecting portion on the one surface in the thickness direction of the chip without providing with the connecting portion piercing through the chip 20 on the other surface in the thickness direction, it is possible to achieve the effect of reduction of a load on the module 21 in the same manner.

The main information terminals A0 to A7 are terminals also referred to as address lines, connected to the terminal bases 41, provided with bump-like connecting portions 44 protruding toward the one surface direction in the thickness direction of the chip from the terminal bases formed on the one surface in the thickness direction of the chip, and provided with connecting portions 45 that pierce through the chip 20 and are formed on the other surface in the thickness direction of the chip. The main information terminals A0 to A7 of the chip 20 located closest to the board 22 are directly connected to board-side information terminals which are formed on the board 22 and inputs and outputs main information, and the main information terminals A0 to A7 of the remaining chips 20 are connected to the board-side information terminals via the main information terminals A0 to A7 of the chips 20 located closer to the board 22.

Thus, the main information terminals A0 to A7 are commonly connected to the board-side information terminals. The main information terminal group 32 is a terminal group for, in order to give information to be stored in the chip 20 or read out information stored in the chip 20, inputting and outputting the information, and it is possible to store the information into the chips 20 or read out the information from the chips 20, from the board 22.

Even if the order of the main information terminals A0 to A7 change, the main information terminals are equivalent in function through the positions of storing physical memory cells are different. Therefore, the main information terminals A0 to A7 are allocated in order in positions having rotational symmetry. Since the chips 20 are stacked in different attitudes, there exist the chips 20 in which the addresses of the memory cells are different from those associated with the board-side information terminals of the board 22, but the chips are equivalent in function, and therefore, no operational problem occurs. The memory cell is a circuit of the internal circuit.

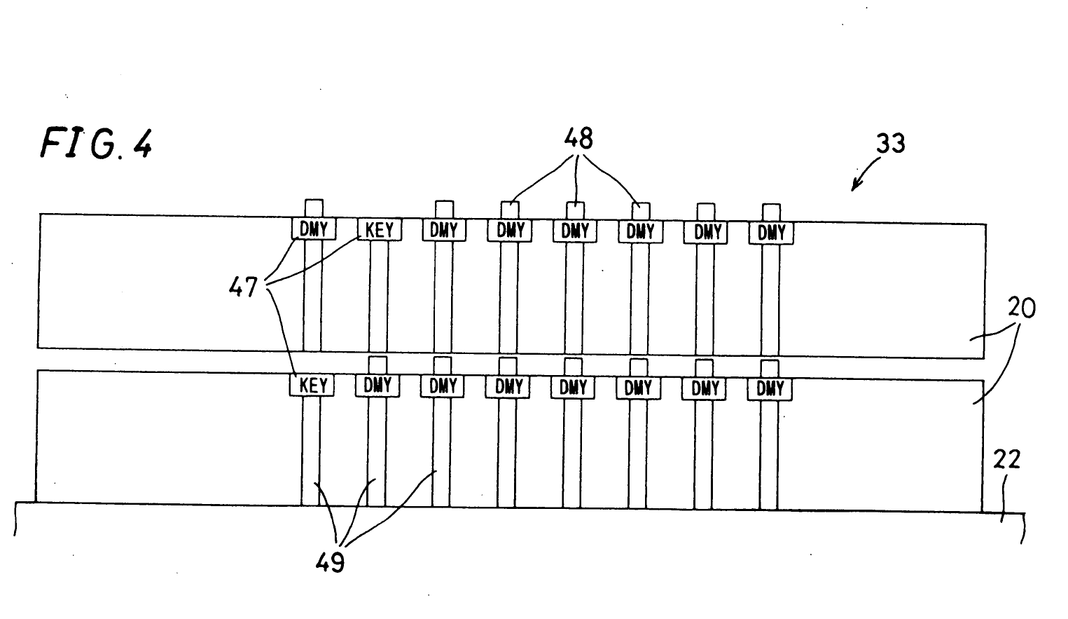

FIG. 4 is a cross section view schematically showing another example of the connection state of the terminals between the adjacent chips 20. FIG. 4 shows the attitude information output terminal group 33 as an example by aligning the terminals KEY, DMY. The terminals KEY, DMY of the attitude information output terminal group 33 are also provided with terminal bases 47 formed on the one surface in the thickness direction of the chip 20.

The reference terminal KEY is connected to the terminal base 47, and provided with a connecting portion 49 that pierces through the chip 20 and is formed on the other surface in the thickness direction of the chip. The reference terminal KEY may be provided with or may not be provided with a connecting portion formed on the one surface in the thickness direction of the chip, and the connecting portion is not formed in the present embodiment. Thus, the reference terminal KEY is provided with a connecting portion formed only on at least one surface of the surfaces in the thickness direction of the chip, in concrete, only on the surface closer to the board 22. The dummy terminal DMY is connected to the terminal base 47, and provided with a bump-like connecting portion 48 that protrudes toward the one surface direction in the thickness direction from the terminal base 47, formed on the one surface in the thickness direction of the chip, and provided with the connecting portion 49 that pierces through the chip 20 and is formed on the other surface in the thickness direction of the chip.

With such a configuration, the reference terminal KEY of the chip 20 located closest to the board 22 is directly connected to a board-side attitude terminal (not shown) for obtaining the attitude of the chip 20 formed on the board 22, and the reference terminals KEY of the remaining chips 20 are connected to the board-side attitude terminal via the dummy terminals DMY of the chips 20 located closer to the board 22. Thus, the reference terminals KEY are individually connected to the board-side attitude terminal.

The attitude information output terminal group 33 is a terminal group used for obtaining the attitude of the chip 20 by the board 22. The reference terminal KEY is controlled from outside to output information representing valid as key data at high impedance. That is to say, the reference terminal KEY is connected to a circuit of the internal circuit that outputs information representing valid (occasionally referred to as “valid information” hereinafter) in response to an output request from the board 22.

Thus, the dummy terminal DMY is controlled from outside to output invalid data at low impedance or to be brought into a floating state, that is, a state in which information from the other chip 20 is transmitted to the board 22. That is to say, the dummy terminal DMY is connected to a circuit of the internal circuit that is switched between a first state and a second state. The first state is a state in which information representing invalid (occasionally referred to as “invalid information” hereinafter) taking priority to information representing valid on the board 22 is outputted in response to an output request from the board 22. The second state is a state of noninterfering with the dummy terminal DMY.

Switching between the first state and the second state may be conducted by using another terminal group, for example, one of the remaining terminal groups 34, 35 of the aforementioned six terminal groups as a state switching terminal group. In this case, this terminal group is a common connection terminal group commonly connected to the board 22, and is configured so that a state command for selecting the first state or the second state is given thereto from the board 22. It is possible to specify the chip by using the chip specific terminal group 31, give the state command to the chip, and switch the state of each of the chips.

By using the attitude information terminal group 33, it is possible to conduct detection of the attitudes of the chips 20 and identification of the module 21 by the board 22. Describing an identification method of the module 21 in concrete, firstly, the chips 20 are brought into the first state, and the board 22 addresses an output request of attitude information. Consequently, valid information is outputted from the reference terminals KEY of the chips 20, and invalid information is outputted from the dummy terminals DMY of the chips 20. Since the reference terminal KEY is not provided with a connecting portion formed toward the opposite side to the board 22, the dummy terminal DMY is not connected in the chip 20 closest to the board, and the board 22 adopts valid information from the board terminal KEY closest to the board. Since the dummy terminal DMY of the other chip 20 is connected to each of the reference terminals KEY of the remaining chips 20, the board 22 preferentially adopts invalid information outputted from the dummy terminal DMY. Accordingly, the position of the reference terminal KEY of the chip 20 closest to the board 22 is detected, and the attitude of the chip 20 closest to the board 22 is detected at first.

Next, the chip 20 whose attitude has been detected, here, the chip 20 closest to the board is specified, the specified chip 20 is brought into the second state, the remaining chips 20 are kept in the first state, and the board 22 addresses an output request of attitude information. Consequently, valid information is outputted from the reference terminal KEY of each of the chips 20, and invalid information is outputted from the dummy terminals DMY of the remaining chips 20 excluding the chip 20 whose attitude has already been detected, that is, excluding the chip 20 closest to the board. Since the reference terminal KEY is not provided with a connecting portion formed toward the opposite side to the board 22, the dummy terminal DMY kept in the second state is not connected to the reference terminal KEY of the second chip 20 from the board, and the board 22 adopts valid information from the board terminal KEY of the second chip 20 from the board. Since the dummy terminals DMY kept in the second state of the other chips 20 are connected to the reference terminals KEY of the remaining chips 20 that are third and more from the board, the board 22 preferentially adopts invalid information outputted from the dummy terminal DMY. Accordingly, the position of the reference terminal KEY of the second chip 20 from the board is detected, and the attitude of the second chip 20 from the board is detected.

Thus, it is possible, while switching the chips 20 whose attitudes have been detected to the second state in order, to detect the position of the reference terminal KEY of one of the chips kept in the first state and detect the attitude. That is to say, it is possible to detect the positions of the reference terminals KEY and detect the attitudes in the order of the chips closer to the board. Thus, it is possible to conduct detection of the attitudes of the chips 20 and identification of the module 21 by the board 22.

The reference terminal KEY is not provided with a connecting portion with the chip 20 on the opposite side to the board 22. With such a configuration, it is possible, while switching a state in the aforementioned manner, to detect the attitudes of the chips 20.

Although the chips are in the face-up state in the present embodiment, in the case where the chips 20 are stacked in the face-down state in another embodiment of the invention, it becomes possible to detect the attitude by providing the reference terminal KEY with only a bump-like connecting portion formed on the one surface in the thickness direction of the chip 20 without providing with a connecting portion that pierces through the chip 20 on the other surface in the thickness direction.

Further, in the case where the reference terminal KEY is provided with connecting portions formed on both the sides in the thickness direction, it is possible, by specifying the chip 20 and bringing only the specified chip 20 into the first state, to detect the attitude of the specified chip 20. Thus, it is possible to detect the attitudes of the chips 20, and identify the module 21. This method can also be adopted in the case where the reference terminal KEY is provided with a connecting portion formed only on one surface of the surfaces in the thickness direction of the chip 20 as shown in FIG. 4.

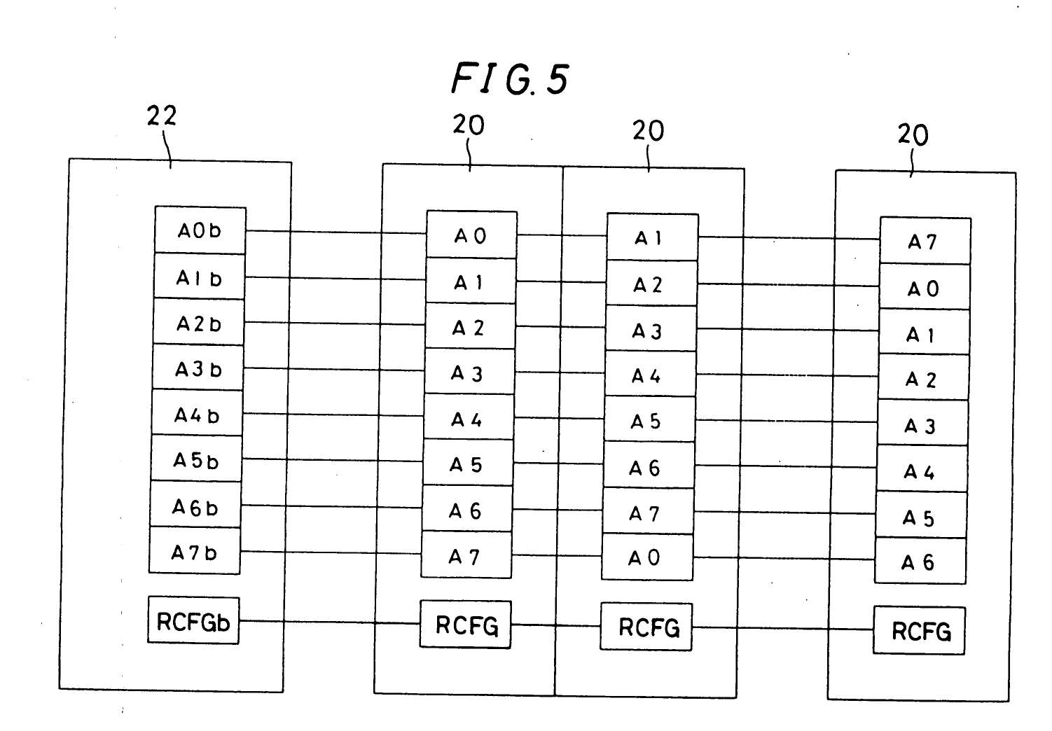

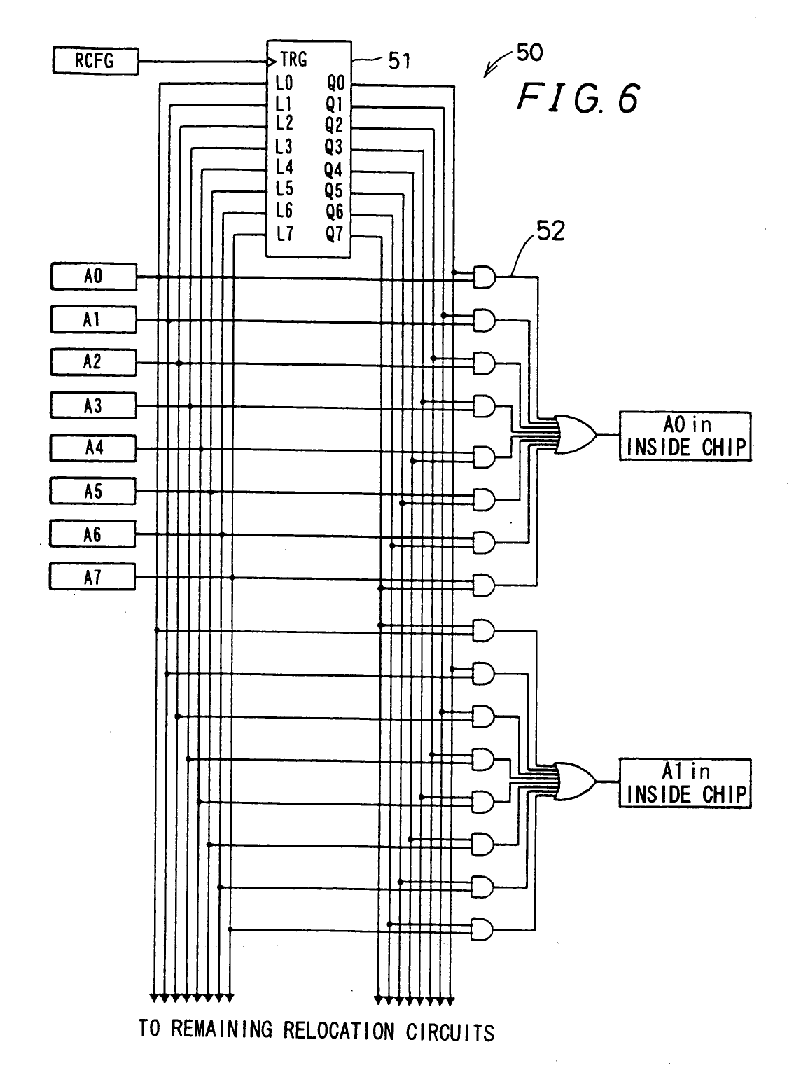

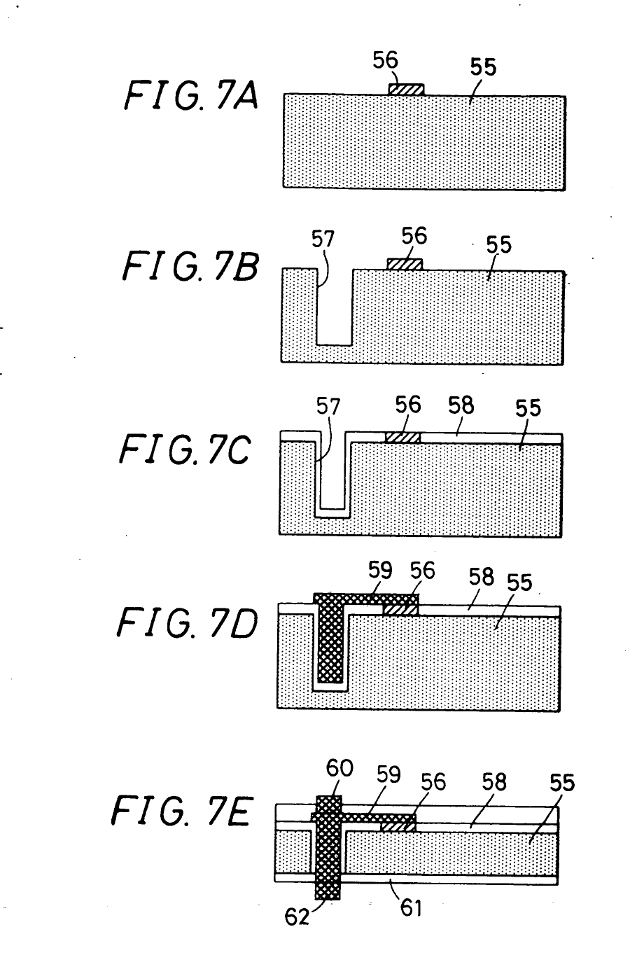

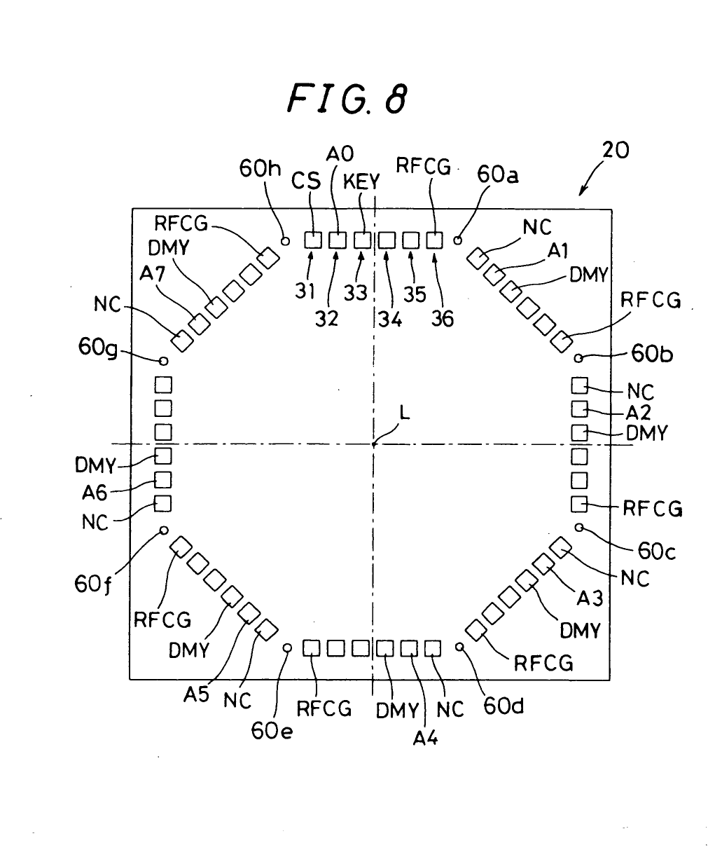

FIG. 5 is a view for explaining a method of setting an operation environment in the chip 20. FIG. 6 is a circuit view showing a circuit 50 for setting an operation environment in the chip 20. In FIG. 5, the board-side information terminals are denoted by reference numerals A0b to A7b, respectively. In FIG. 6, in order to facilitate the illustration, regarding connection of the main information terminals to the inside of the chip, that is, to the internal circuit, only the main information terminals A0, A1 are shown, but the remaining main information terminals A2 to A7 have the same configuration. As described before, there is no influence on operation even if the addresses of the memory cells connected to the main information terminals A0 to A7 do not coincide with the addresses on the board 22, but in order to realize the favorable module 21, it is preferred to execute the setting of an operation environment, which is referred to as terminal relocation, so as to make the addresses of the memory cells of the chips 20 coincide with the addresses on the board 22.

The chip 20 has the circuit 50 that sets an operation environment appropriate to the stacking state of the chip 20 on the basis of a setting command given from the board 22, in the internal circuit. Moreover, command input terminals RCFG of the command input terminal group 36 are provided with connecting portions formed on the surfaces on both the sides in the thickness direction in the same manner as the main information terminals A0 to A7 of the main information input-output terminal group 32, and commonly connected to board-side command terminals RCFGb formed on the board 22. The command input terminal group 36 is a terminal group to which a setting command as a command for setting an operation environment appropriate to the stacking state in each of the chips 20 is given from the board 22, and the setting command from the board 22 is given thereto in common.

Setting of an operation environment is executed on the basis of information representing the addresses of the board-side information terminals A0b to A7b given to the main information terminals A0 to A7, for example, when a setting command for commanding relocation is given to the command input terminals RCFG. In concrete, while the setting command is given, as address information of the board-side information terminals A0b to A7b, information representing valid, for example, “high (H) level” (occasionally referred to as “valid information” hereinafter) is given from the one board-side information terminal A0b, and information representing invalid, for example, “low (L) level” (occasionally referred to as “invalid information” hereinafter) is given from each of the remaining board-side information terminals A1b to A7b.

In this case, a terminal to which valid information is given among the main information terminals A0 to A7 is different in each of the chips 20. On the basis of the information, that is, to which terminal of the main information terminals A0 to A7 valid information is given, each of the chips 20 can grasp the attitude thereof, and on the basis of the attitudes, the relations between the main information terminals A0 to A7 and the memory cells are set and stored in the chips 20 so that it is possible to read from and write into the memory cells having addresses that coincide with the addresses of the board-side information terminals A0b to A7b by reading and writing by the board-side information terminals A0b to A7b. That is to say, the circuit 50 is realized by including a storing portion 51 that stores information on a shift in the rotation direction, namely, information on the attitude, and a data selector portion 52.

The storing portion 51 and the data selector portion 52 will be described by showing only connection of the main information terminals A0, A1 to the inside of the chip. A setting command is given as a trigger of the storing portion 51. Valid information and invalid information given to the main information terminals A0 to A7 are given, and a setting command is given, whereby the storing portion stores the valid information and the invalid information given to the main information terminals A0 to A7. Then, the storing portion can give the stored and kept valid information and invalid information to the data selector portion 52.

The data selector portion 52 is a circuit that associates the main information terminals A0 to A7 with internal terminals A0in to A7in (A2in to A7in are not shown) annexed to the memory cells. This data selector portion 52 is realized by an AND-OR circuit. The AND-OR circuit, for each of the internal terminals A0in to A7in, has a logical operation circuit including AND elements which associate one of the main information terminals A0 to A7 with one of terminals Q0 to Q7 of the storing portion 51 and find logical products of outputs, respectively, and an OR element which finds the logical sum of outputs of the AND elements, and is configured so that association of the terminals for finding logical products by the eight AND elements differs for each of the internal terminals A0in to A7in.

It is assumed that valid information is given from the board-side information terminal A0b and invalid information is given from each of the remaining board-side information terminals A1b to A7b. When a setting command is given, the valid information and the invalid information given to the terminals A0 to A7 are given to the storing portion 51 through terminals L0 to L7, and it becomes possible to output the information from each of the terminals Q0 to Q7. The main information terminals A0 to A7 and the internal terminals A0in to A7in are connected via the AND-OR circuit 52, and a correspondence is set on the basis of the information from each of the terminals Q0 to Q7 of the storing portion 51.

With such a configuration, in a chip 20 that valid information is given to the main information terminal A0, on the basis of the valid information and valid information from the storing portion 51, the main information terminal A0 and the internal terminal A0in are associated. Moreover, in a chip 20 that the attitude is shifted and valid information is given to the main information terminal A1, on the basis of the valid information and valid information from the storing portion 51, the main information terminal A1 and the internal terminal A0in are associated. Thus, in the chips 20, the board-side information terminals and the memory cells are associated so that the addresses coincide with each other.

The circuit 50 that sets an operation environment is not limited to the above configuration, and can be configured by a latch circuit that regards a setting command as a trigger and an AND-OR circuit or a bidirectional switch. Moreover, since the terminals located so as to have rotational symmetry are shifted in the same direction in all of the terminal groups, it is possible to relocate all the terminal groups having rotational symmetry by using a direction determined in one of the terminal groups. Thus, by relocating information, that is, setting an operation environment on the basis of the attitude that the chip is stacked and mounted, the degree of freedom of locating information to the terminals having rotational symmetry increases, which is favorable.

FIGS. 7A to 7E are cross section views showing an example of a process of forming a terminal. In FIGS. 7A to 7E, a process of forming the connecting portions on the surfaces on both the sides in the thickness direction. As shown in FIG. 7A, the terminal forming process is started in the state where an internal circuit such as a memory cell and an internal terminal 56 annexed there to are formed on a wafer 55. At first, as shown in FIG. 7B, a deep unpiercing hole 57 is formed on the wafer from the one surface side in the thickness direction of the chip 20 by reactive ion etching (RIE) or the like.

Next, as shown in FIG. 7C, an insulating film 58 is formed over the bottom wall and the side wall of the unpiercing hole 57 and the surface of a portion where the internal terminal 56 is formed. In general, the insulating film is formed by chemical vapor deposition (CVD).

Next, as shown in FIG. 7D, a conductor 59 filled into the unpiercing hole 57 and connected to the internal terminal 56 is formed. This conductor 59 may be formed by electroplating of copper (Cu), or may be formed by printing of conductive paste.

Next, as shown in FIG. 7E, a bump-like protruding portion (becomes a connecting portion on the one surface in the thickness direction of the chip to be formed) 60 is formed on the one surface in the thickness direction by electrolytic plating or the like, and subsequently, abrasion is executed from the back of the wafer to make the unpiercing portion 57 pierce and make the conductor 59 exposed. After that, a protecting film 61 and a bump-like protruding portion 62 are formed on the other surface in the thickness direction. The protecting film may be formed with an insulating thin film by CVD or the like, or may be formed by applying polyimide (PI) or the like. The protruding portion 62 should be formed by nonelectrolytic plating, because it may be difficult to form feeder metal.

Thus, the terminal is formed. A portion of the conductor 59 filled into the unpiercing hole 57 and the protruding portion 62 correspond to a connecting portion on the other surface in the thickness direction, and a portion of the conductor 59 sandwiched by the two connecting portions corresponds to a terminal base. It is possible to form a terminal which is not provided with a connecting portion formed on the one surface in the thickness direction of the chip, by omitting the step of forming the protruding portion 60, and it is possible to form a terminal which is not provided with a connecting portion formed on the other surface in the thickness direction, by omitting the step of forming the unpiercing hole, the step of filling the conductor and the step of forming the protruding portion 60.

FIG. 8 is a front view of the chip 20 for explaining the location of alignment marks 60a to 60h. On the chip 20, the alignment marks 60a to 60h used for positioning on stacking the chips 20 are located and formed so as to have the same symmetry as symmetry of the terminals. That is to say, the alignment marks have rotational symmetry of the same number of rotations about the rotational symmetry axial line L of the terminals. By forming these alignment marks 60a to 60h, on stacking the chips 20, it is possible to position, stack and mount the chips without time and effort for correction with respect to a reference mark and so on even if the attitudes are shifted because the alignment marks exist in positions having rotational symmetry equivalent at all times, which is favorable.

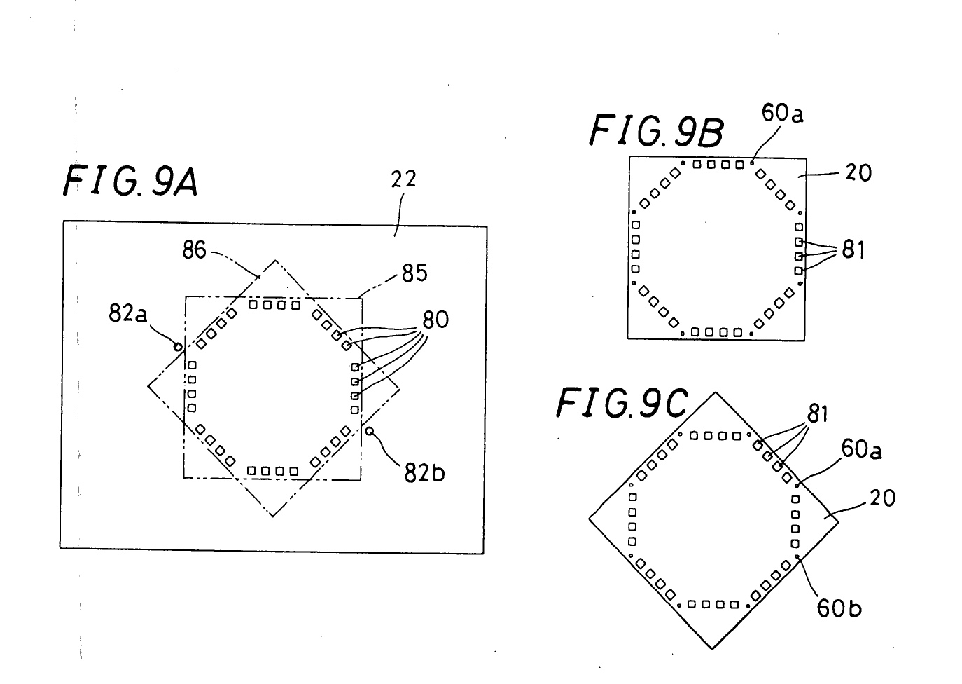

FIGS. 9A to 9C are views for explaining a method of stacking the chips 20 by using the alignment marks 60a to 60h. Since FIGS. 9A to 9C are views for explaining how to use the alignment marks, the number of the terminals is reduced, and the terminals are generically named and denoted by reference numeral 81, in order to make it easy to understand. As shown in FIG. 9A, terminals 80 are formed on the board 22 so as to have rotational symmetry about the axial line L. Moreover, at least one board-side alignment mark, in the present embodiment, two board-side alignment marks 82a, 82b are formed on the board 22. The chip 20 is stacked either in the state where the external shape coincides with the board 22 as shown in FIG. 9B or in the state where the external shape is oblique with respect to the board 22 as shown in FIG. 9C. In the state shown in FIG. 9B, the chip 20 is put on the board 22 in the state as shown by a virtual line 85, and in the state shown in FIG. 9C, the chip 20 is put on the board 22 in the state as shown by a virtual line 86. The attitudes shown in FIGS. 9B, 9C are examples, and include attitudes equivalent thereto.

The board-side alignment marks 82a, 82b are located outside a region of the chips 20 projected on the board 22. That is to say, since the board-side alignment marks 82a, 82b need to be visible when all the chips 20 are stacked, the board-side alignment marks are positioned outside the external shapes of the stacked chips 20. On stacking the chips 20, the alignment marks 60a to 60h of the chips 20 are selectively used to position the chips to the board-side alignment marks 82a, 82b. Thus, the alignment marks 60a to 60h having the same rotational symmetry as the terminals are formed on the chips 20, and the alignment marks 82a, 82b of the minimum necessary number are formed on the board 22. In the case where one board-side alignment mark is sufficient, for example, in the case where a position on the board to locate the rotational symmetry axial line of the chip 20 can be specified, only one board-side alignment mark is may be formed.

According to the chip 20 of the present embodiment, the terminals of the common connection terminal groups such as the main information input-output terminal group 31 and the setting command terminal group 36 are formed so as to have rotational symmetry of a predetermined fold-number, and provided with connecting portions formed on both the surfaces in the thickness direction. Moreover, the terminals of each of the individual connection terminal groups such as the chip specific terminal group 31 and the attitude information output terminal group 33 are formed so as to have rotational symmetry of a predetermined fold-number, the specific terminal as one of the terminals is provided with a connecting portion formed on at least one surface of the surfaces in the stacking direction of the chip, and the related terminals as the rest of the terminals are provided with connecting portions formed on both the surfaces in the stacking direction of the chip.

Thus, by the assembly method as described above, the chips 20 with the terminals formed in symmetric locations are stacked so as to be shifted from each other by an angle obtained by dividing 360 degrees by the setting number of rotations, and the connecting portions of the terminals of the electronic components adjacent to each other in the stacking direction are connected to each other. Consequently, it is possible to easily assemble the module 21 in which the terminals of the common electrode terminal groups are commonly connected to the board 22 and the specific terminals of the individual connection terminal groups are individually connected to the board 22. Consequently, on stacking the plurality of chips 20 to assemble the module 21, it is possible to use the chips 20 having the same configuration without preparing the chips 20 having different configurations. Accordingly, it is possible to reduce time and effort to manufacture the chips 20 for stacking and assembling the module 21, and manufacture the chips 20 with ease.

Further, the chips 20 are stacked so that one surfaces in the thickness direction of the chips are directed to the same direction, and can easily form the module 21 in which location of the terminals is simple and the number of layers is equal to or less than the predetermined fold-number. Moreover, the specific terminal is provided with a connecting portion formed only on one surface of the surfaces in the stacking direction of the chip, and it is possible to make a portion connected to the board 22 small. Consequently, it is possible to reduce a load on the module 21 on driving and controlling the module 21 from the board 22, and it is possible to contribute to making the module 21 high-speed and have a high-level function.

Further, the chips 20 have the attitude information output terminal groups 33 as one of the individual connection terminal groups, and output valid information from the reference terminals KEY in response to an output request from the board 22 to the terminals KEY, DMY while switching the dummy terminals DMY of the attitude information output terminal groups 33, thereby being capable of giving information on the positions of the reference terminals KEY of the chips 20 to the board 22. Consequently, it is possible to give information representing the attitude of each of the chips 20 to the board 22. That is to say, as an identification method of a module, an output request is given from the board 22 to each of the terminals KEY, DMY of the attitude information terminal group 33. Consequently, it is possible to obtain valid information from the reference terminal KEY of the attitude information terminal group 33 of each of the chips 20, and it is possible to detect the position of the reference terminal KEY. Consequently, it is possible to detect the attitude of each of the electronic components in the module, and it is possible to detect the alignment of the electronic components in the module. Accordingly, it is possible to identify the module on the basis of a difference in alignment.

Further, the chip 20 has the internal circuit that sets an operation environment appropriate to a stacking state, that is, the circuit 50, and has the command input terminal group 36 as one of the common connection terminal groups. When a setting command is given from the board 22 to the command input terminal group 36, an operation environment appropriate to a stacking state is set by the circuit 50. That is to say, as an environment setting method of the module, a setting command is given to the terminals RFCG of the command input terminal group 36. When a setting command is given, each of the chips 20 sets an operation environment in response to the setting command. Consequently, it is possible to set an operation environment in each of the chips 20. Consequently, it is possible to give a setting command and set an operation environment after stacking the plurality of chips 20 and forming the module 21, and it is possible to obtain the highly convenient module 21 that favorably operates.

Further, on each of the chips 20, the alignment marks 60a to 60h used for positioning on stacking are located so as to have the same symmetry as the terminals. Consequently, by forming at least one alignment mark of the minimum number, in the present embodiment, the two alignment marks 82a, 82b on the board 22, it is possible to position the chips 20 in positions shifted from each other by an angle obtained by dividing 360 degrees by the predetermined fold-number. That is to say, it is possible to position the chips by using the alignment marks 82a, 82b formed on the board 22.

On positioning, at least one alignment mark is sufficient on the board 22. The chip 20 is formed more accurately than the board 22, and the alignment marks 60a to 60h on the chip 20 are formed more accurately than the alignment marks 82a, 82b on the board. By forming the alignment mark 60a on the chip 20 so as to have symmetry as described before, it is possible to position the chips by using the highly accurate alignment marks 60a to 60h on the chip 20 as much as possible, and it is possible to position the chips with high accuracy, so that it is possible to assemble the highly accurate module 21.

Furthermore, by symmetrically locating the terminals of the common connection terminal groups, it is possible to avoid forming a region in which only the terminals of the individual connection terminal group can be disposed, and make the number of the terminals of the common connection terminal group hard to be limited. Consequently, it is possible to make constraints on a bus width, that is, on the amount of data that can be transmitted per unit time by using the common connection terminals as small as possible.

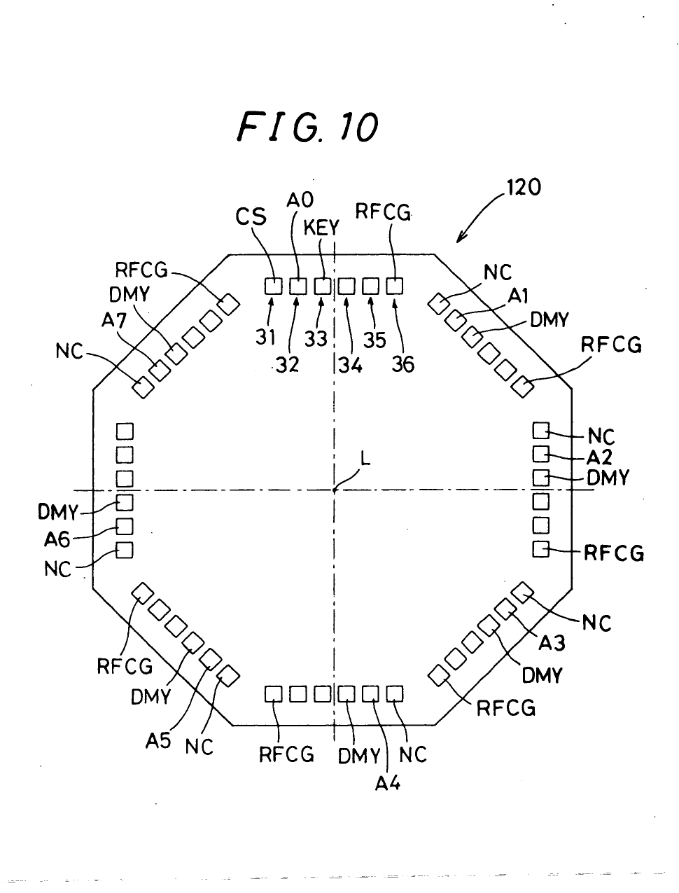

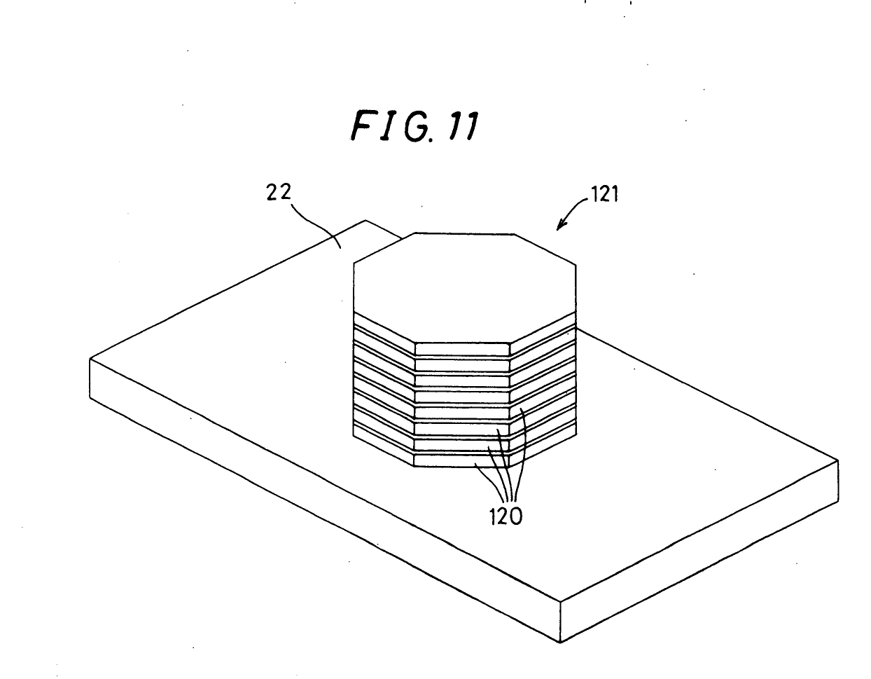

FIG. 10 is a front view showing a chip 120 according to another embodiment of the invention. FIG. 11 is a perspective view showing a module 121 assembled by stacking the chips 120. Since the chip 120 shown in FIGS. 10, 11 is similar to the chip 20 of the embodiment shown in FIGS. 1 to 9, corresponding components will be denoted by the same reference numerals, and only different components will be described. The chip 120 shown in FIGS. 10, 11 is formed, in external shape perpendicular to the thickness direction, into a regular polygon having the same number of angles as the predetermined fold-number, accordingly, a regular octagon in the present embodiment.

The chips 120 achieve the same effect as the aforementioned chip 20, and moreover, can be stacked with the rim portions lined up when stacked. That is to say, the chips are stacked so that the external shapes of the chips 20 fit when viewed in the thickness direction (stacking direction). Consequently, it is possible to make an occupied space necessary for locating the module as small as possible, which is favorable because a useless portion is not generated.

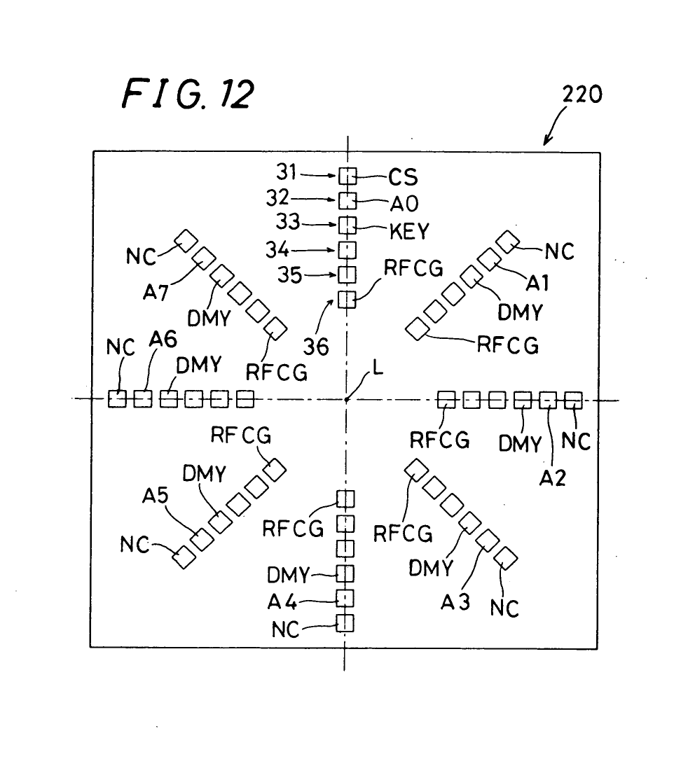

FIG. 12 is a front view showing a chip 220 according to still another embodiment of the invention. Since the chip 220 shown in FIG. 12 is similar to the chip 20 of the embodiment shown in FIGS. 1 to 9, corresponding components will be denoted by the same reference numerals, and only different components will be described. On the chip 220 shown in FIG. 12, the terminals of the terminal groups 31 to 36 are located radially, not peripherally. Also with such a configuration, it is possible to achieve the same effect as the aforementioned chip 20. That is to say, as far as the terminals are located so as to have rotational symmetry, it is possible to achieve the same effect regardless of the location.

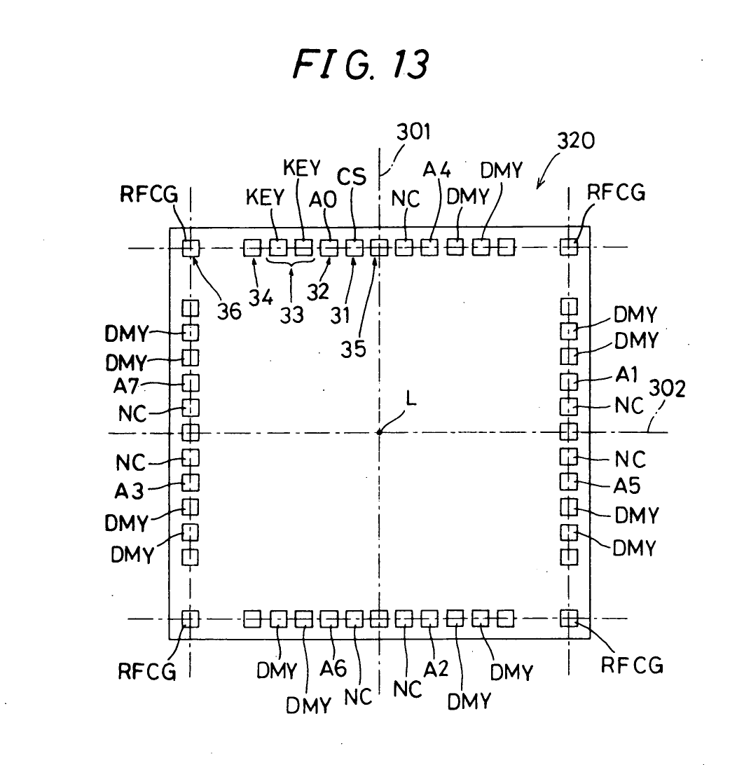

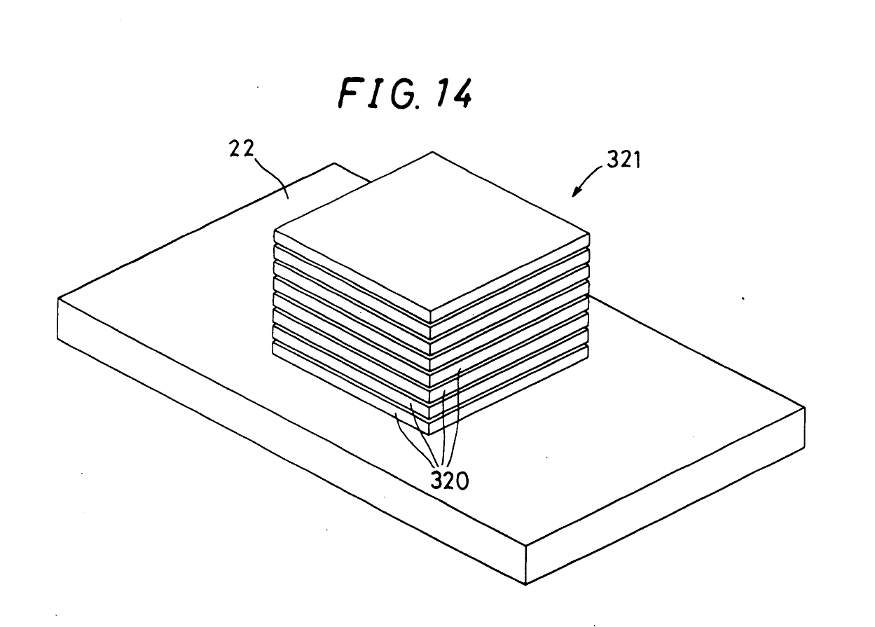

FIG. 13 is a front view showing a chip 320 according to still another embodiment of the invention. FIG. 14 is a perspective view showing a module 321 assembled by stacking the chips 320. Since the chip 320 shown in FIGS. 13, 14 is similar to the chip 20 of the embodiment shown in FIGS. 1 to 9, corresponding components will be denoted by the same reference numerals, and only different components will be described. As to the chip 320 shown in FIGS. 13, 14, on stacking the plurality of chips 20, at least one of the chips 320 is stacked so that the one surface in the stacking direction of the at least one chip 320 is directed to one direction, and the remaining chips 320 are stacked so that other surfaces in the stacking direction of the remaining chips 320 are directed to the one direction.

On the chip 320, the terminals of each of the terminal groups 31 to 36 are located so as to have rotational symmetry of a predetermined fold-number (N-fold symmetry) about the symmetry axial line L parallel to the thickness direction, and in addition, so as to have line symmetry with respect to a symmetry line passing through the center of rotation symmetry, that is, so as to have plane symmetry with respect to a symmetry plane including the symmetry axial line L. The symmetry plane may be one of planes 301, 302 that are parallel to the rim portions of the chip 20, for example. In the present embodiment, the predetermined fold-number of rotation symmetry is a natural number multiple of 2 (N is a natural number multiple of 2), and concretely, the predetermined fold-number is 4.

In the case of locating the terminals so as to have rotational symmetry and line symmetry in this manner, regarding the terminals having absolutely the same configuration among the terminals of the common connection terminal groups, the terminal groups 31 to 36 have terminals of a natural number multiple of the predetermined fold-number, and the chip may be configured so as to have terminal groups located so that the position of rotation symmetry coincides with the position of line symmetry. In the present embodiment, the terminal groups 35, 36 are located so that the position of rotation symmetry coincides with the position of line symmetry.

The chip specific terminal group 31 has eight terminals, which is two times the predetermined fold-number, and the eight terminals include one chip specific terminal CS and the seven non-connection terminals NC. The main information input-output terminal group 32 has the eight main information terminals A0 to A7, which is two times the predetermined fold-number. The attitude information output terminal group 33 has sixteen terminals, which is four times the predetermined fold-number, and the sixteen terminals includes the two reference terminals KEY and the fourteen dummy terminals DMY. The command input terminal group 36 has four command terminals RFCG, which is one time the predetermined fold-number.

The plurality of chips 320 with the terminals thus formed are stacked so that the attitudes are shifted from each other about the axial line L by an angle obtained by dividing 360 degrees by the predetermined fold-number (occasionally referred to as “set angle” hereinafter; 90 degrees obtained by dividing 360 degrees by 4 in the embodiment shown in FIGS. 13, 14), or so as to be inverted in the thickness direction. The number of stacked chips should be two or less times the predetermined fold-number, in the present embodiment, eight, which is two times the predetermined fold-number, and the eight-layer module 321 is configured by using the eight chips 20.

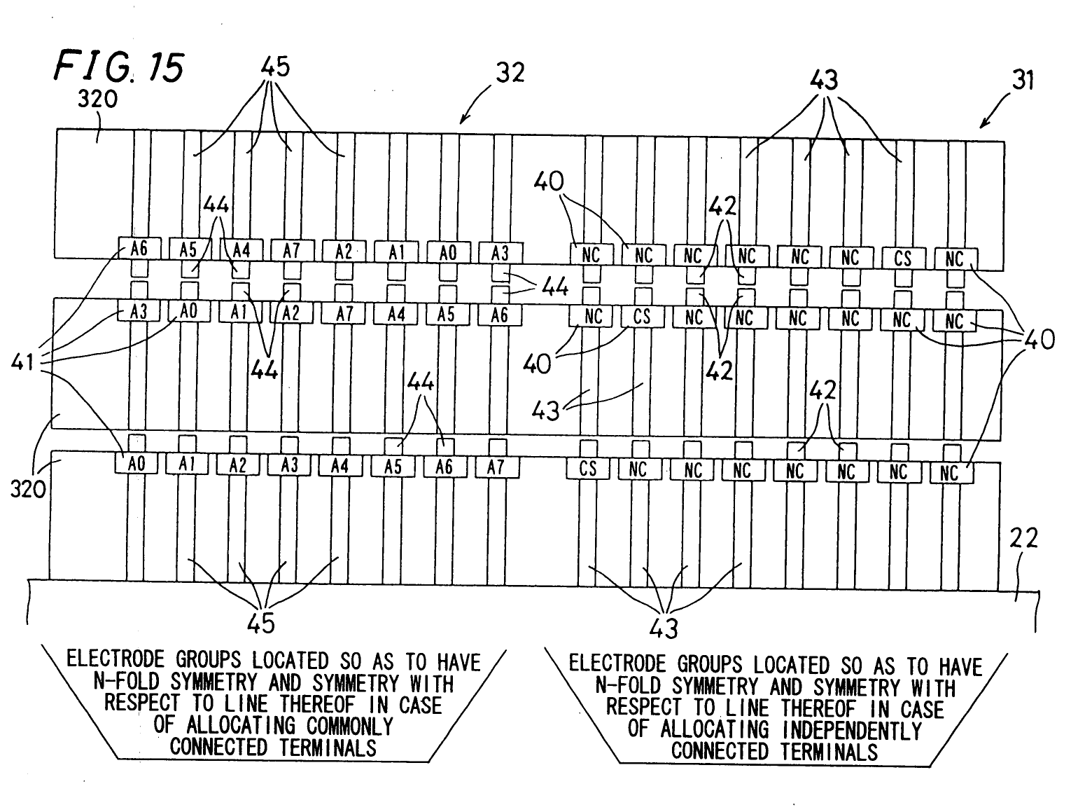

FIG. 15 is a cross section view schematically showing an example of the connection state of the terminals among the adjacent chips 320. Moreover, in FIG. 15, in order to make it easy to understand, the three chips are shown by aligning the terminals CS, NC of the chip specific terminal groups 31 on the right side and aligning the terminals A0 to A7 of the main information input-output terminal groups 32 on the left side.

The terminals of the terminal groups 31 to 36 are provided with terminal bases formed on the one surface in the thickness direction of the chip 20. On stacking the chips 20, half of the chips 320, that is, four of the chips 320 are stacked in a manner that the one surfaces in the thickness direction of the chips 320 with the terminal bases formed are directed to one direction, in concrete, in the face-up state in which the terminal bases are directed to the opposite side to the board 22, and the remaining half, that is, four of the chips 320 are stacked in a manner that the one surfaces in the thickness direction of the chips 320 with the terminal bases formed are directed to the other direction, in concrete, in the face-down state in which the terminal bases are directed to the board 22.

The chips are directed to the same direction, that is, the face-up chips 320 and the face-down chips 320 are stacked, respectively, in different attitudes shifted from each other so as not to be located in the same attitude. The terminals CS, NC of the chip specific terminal group 31 and the terminals A0 to A7 of the main information input-output terminal group 32 are also provided with terminal bases 40, 41, respectively, on the one surface in the thickness direction of the chip 20.

The chip specific terminal CS and the non-connection terminals NC are connected to the terminal bases 40, and provided with bump-like connecting portions 42 protruding toward the one surface side in the thickness direction of the chip 20 from the base terminals, formed on the one surface in the thickness direction of the chip, and provided with connecting portions 43 that pierce through the chip 20 and are formed on the other surface in the thickness direction of the chip. With such a configuration, the chip specific terminal CS of the chip 20 located closest to the board 22 is directly connected to the board-side specific terminal, and the chip specific terminals CS of the remaining chips 20 are connected to the board-side specific terminal via the non-connection terminals NC of the chips 20 located closer to the board 22. Thus, the chip specific terminals CS are individually connected to the board-side specific terminal.

The main information terminals A0 to A7 are connected to the terminal bases 41, and provided with bump-like connecting portions 44 protruding toward the one surface side in the thickness direction of the chip from the terminal bases, formed on the one surface in the thickness direction of the chip, and provided with connecting portions 45 that pierce through the chip 20 and are formed on the other surface in the thickness direction. The main information terminals A0 to A7 of the chip 20 located closest to the board 22 are directly connected to the board-side information terminals which are formed on the board 22 and inputs and outputs main information, and the main information terminals A0 to A7 of the remaining chips 20 are connected to the board-side information terminals via the main information terminals A0 to A7 of the chips 20 located closer to the board 22.

Thus, the main information terminals A0 to A7 are commonly connected to the board-side information terminals. The main information terminal group 32 is a terminal group which, in order to give information to be stored to the chip 20 or read out information stored in the chip 20, inputs and outputs the information, and it is possible to store the information into the chips 20 or readout the information from the chips 20, by the board 22.

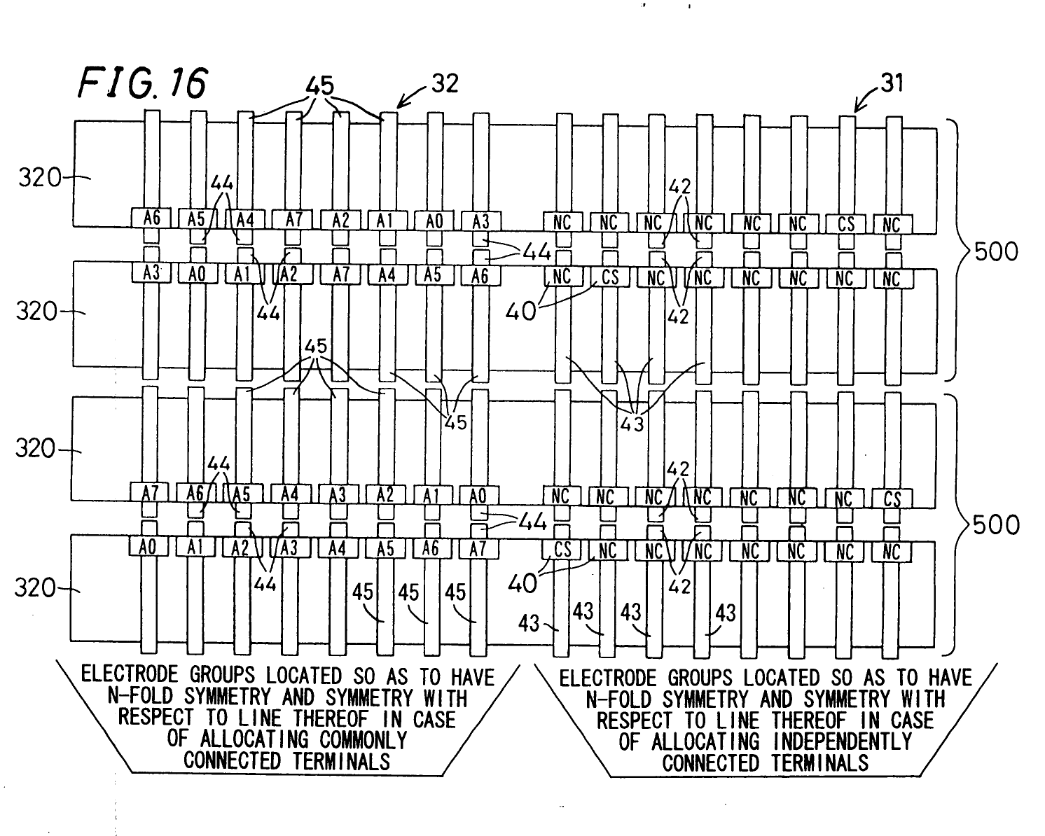

FIG. 16 is a cross section view schematically showing another example of the connection state of the terminals among the adjacent chips 320. Regarding the stacking order, the chips may be stacked by gathering the chips to be mounted in the face-up state and the chips to be mounted in the face-down state, respectively, but by stacking the chip to be mounted in the face-up state and the chip to be mounted in the face-down state in the same attitude, that is, making the principal surfaces of the two chips 20 face each other to configure a unit 500 as a pair of electronic components, and stacking the units 500 while shifting the attitudes thereof as shown in FIG. 16, it is possible to easily identify a difference in attitude, which is more favorable.

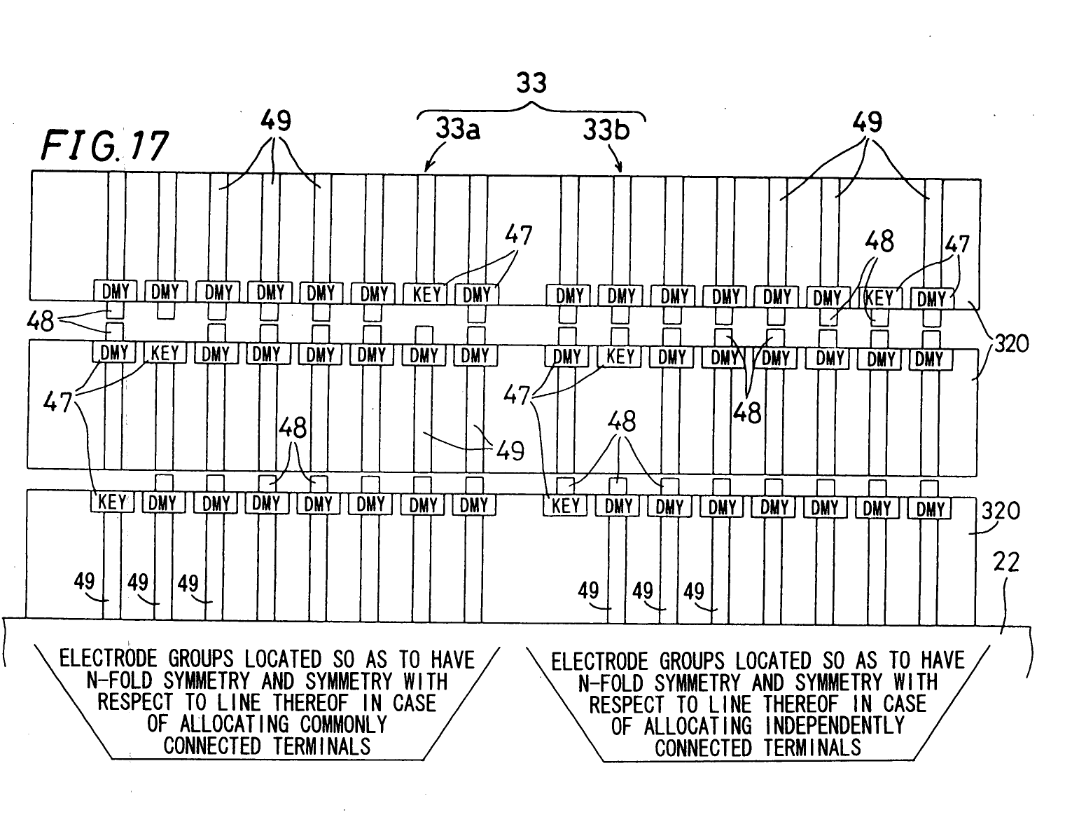

FIG. 17 is a cross section view schematically showing another example of the connection state of the terminals among the adjacent chips 320. In FIG. 17, the attitude information output terminal group 33 is shown as an example. The attitude information terminal group 33 is divided into two groups 33a, 33b, the groups 33a, 33b have eight terminals located so as to have rotational symmetry and line symmetry described before, respectively, the eight terminals of each of the groups 33a, 33b include the one reference terminal KEY and the seven dummy terminals DMY. FIG. 17 shows the terminals KEY, DMY by aligning in the groups 33a, 33b in order to make it easy to understand. The terminals KEY, DMY of the attitude information output terminal group 33 are also provided with terminal bases 47 formed on the one surface in the thickness direction of the chip 20.

The reference terminal KEY of the one group 33a is connected to the terminal base 47, and provided with a connecting portion 49 that pierces through the chip 20 and is formed on the other surface in the thickness direction. The reference terminal KEY of the one group 33a may be provided with or may not be provided with a connecting portion formed on the one surface in the thickness direction of the chip, and in the present embodiment, the connecting portion is not formed. Moreover, the reference terminal KEY of the other group 33b is connected to the terminal base 47, and provided with a bump-like connecting portion 48 formed on the one surface in the thickness direction of the chip 20. The reference terminal KEY of the one group 33b may be provided with or may not be provided with a connecting portion that pierces through the chip and is formed on the other surface in the thickness direction, and in the present embodiment, the connecting portion is not formed. Thus, the reference terminals KEY are provided with connecting portions formed on only at least one surface of the surfaces in the thickness direction of the chip, specifically, on only one surface, which is different between the group 33a and the group 33b. The dummy terminal DMY is connected to the terminal base 47, and provided with the bump-like connecting portion 48 protruding toward the one surface side in the thickness direction from the terminal base 47, formed on the one surface in the thickness direction of the chip, and provided with the connecting portion 49 that pierces through the chip 20 and is formed on the other surface in the thickness direction of the chip.

With such a configuration, on the chip 20 located closest to the board 22, the reference terminal KEY of one of the groups 33a, 33b, in the present embodiment, the one group 33a is directly connected to the board-side attitude terminal, and on the remaining chips 20, the reference terminals KEY of one of the groups 33a, 33b are connected to the board-side attitude terminal via the dummy terminals DMY of the chips 20 located closer to the board 22. Thus, the reference terminals KEY of one of the groups 33a, 33b of the chips 320 are individually connected to the board-side attitude terminal. With such a configuration, it is possible to conduct detection of the attitudes of the chips 20 and identification of the module 21 by the board 22 in the same process as the process described referring to FIG. 4.

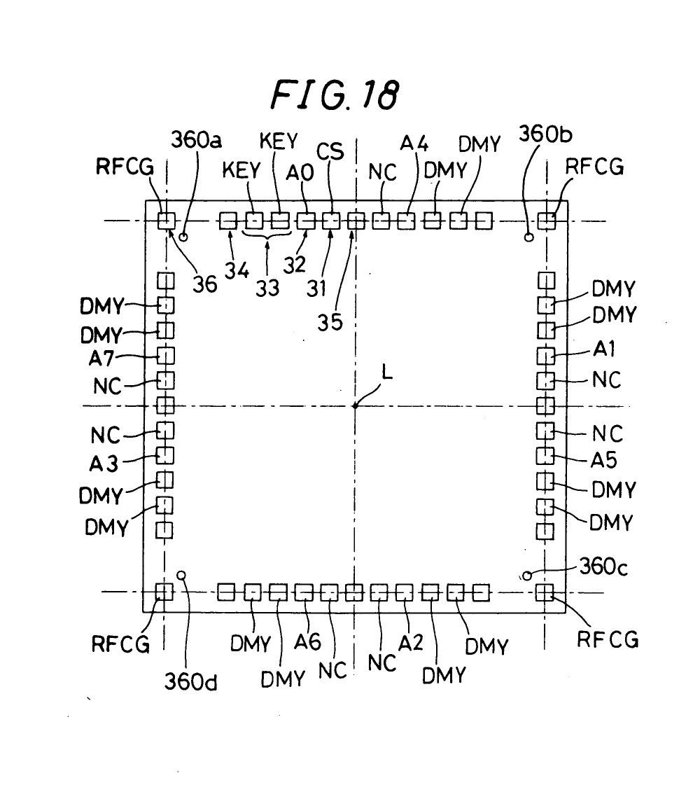

FIG. 18 is a front view of the chip 320 for explaining the location of alignment marks 360a to 360d. On the chip 320, the alignment marks 360a to 360d used for positioning on stacking the chips 320 are located and formed so as to have the same symmetry as symmetry of the terminals. Moreover, in the present embodiment, on both the sides in the thickness direction, the alignment marks 360a to 360d are formed in corresponding positions with respect to the thickness direction. That is to say, the alignment marks have rotational symmetry of the same fold-number about the rotation symmetry axial line L of the terminals. By forming these alignment marks 360a to 360d, on stacking the chips 20, it is possible to position, stack and mount the chips without time and effort for correction with respect to a reference mark and so on even if the attitudes are shifted by rotation or inversion because the alignment marks exist in positions having rotational symmetry equivalent at all times, which is favorable.

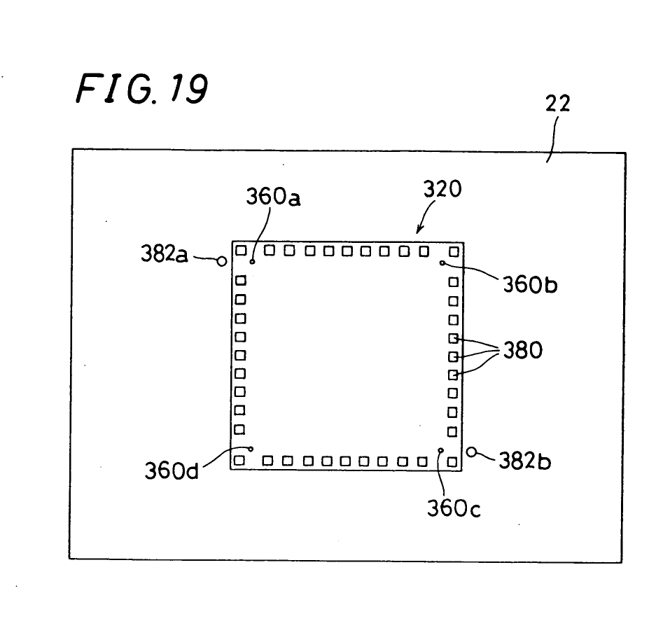

FIG. 19 is a view for explaining a method of stacking the chips 20 by using the alignment marks 360a to 360d. Since FIG. 19 is a view for explaining how to use the alignment marks, the number of the terminals is reduced, and the terminals are generically named and denoted by reference numeral 380, in order to make it easy to understand. At least one board-side alignment mark, in the present embodiment, two board-side alignment marks 382a, 382b are formed on the board 22. The chips 320 are stacked in the state in which the external shapes fit the board 22. The attitude shown in FIG. 19 is an example, and includes attitudes equivalent thereto.

The board-side alignment marks 382a, 382b are located outside a region of the chips 320 projected on the board 22. That is to say, since the board-side alignment marks 382a, 382b need to be visible when all the chips 320 are stacked, the alignment marks are positioned outside the external shapes of the stacked chips 20. On stacking the chips 320, the alignment marks 360a to 360d of the chips 320 are selectively used to position the chips to the board-side alignment marks 382a, 382b. Thus, the alignment marks 360a to 360d having the same rotational symmetry as the terminals are formed on the chips 320, and the alignment marks 382a, 382b of the minimum necessary number are formed on the board 22. In the case where one board-side alignment mark is sufficient, for example, in the case where it is possible to specify a position on the board 22 to locate the rotational symmetry axial line of the chip 20, only one board-side alignment mark may be formed.

According to the embodiment shown in FIGS. 13 to 19, it is possible to achieve the same effect as in the embodiment shown in FIGS. 1 to 9. In addition, the terminals have line symmetry with respect to a symmetry line passing through the center of rotational symmetry, and it is possible to stack the chips 320 in the inverted state with respect to the stacking direction, and it is possible even in this state to assemble a module such that the terminals of the common electrode terminal groups are commonly connected to the component outside the module and the specific terminals of the individual connection terminal groups are individually connected to the component outside the module. Accordingly, it is possible to easily form a module such that the number of layers is two or less times the predetermined fold-number.

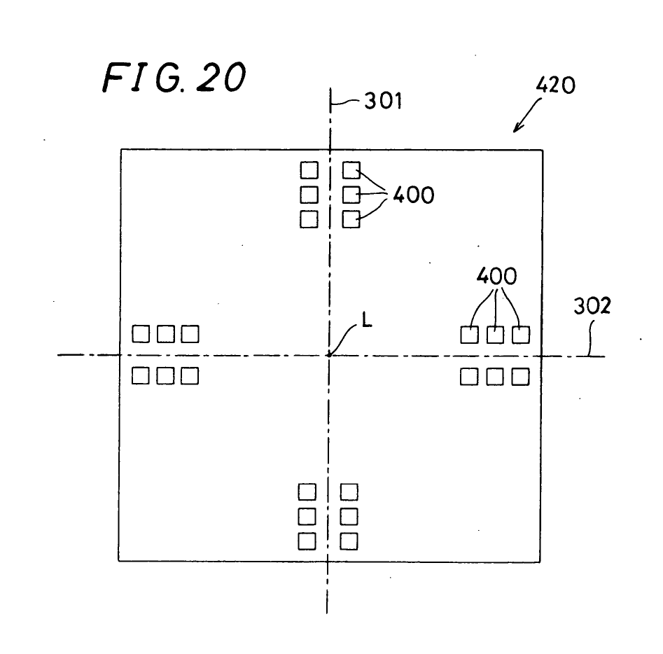

FIG. 20 is a front view showing a chip 420 according to still another embodiment of the invention. In FIG. 20, the number of the terminal groups and the number of the terminals are reduced, and all the terminals are denoted by reference numeral 400, in order to make it easy to understand. Since the chip 420 shown in FIG. 20 is similar to the chip 320 of the embodiment shown in FIGS. 13 to 19, corresponding components will be denoted by the same reference numerals, and only different components will be described. On the chip 420 shown in FIG. 20, the terminals 400 of the terminal groups are located radially, not peripherally. Also with such a configuration, it is possible to achieve the same effect as the aforementioned chip 320. That is to say, as far as the terminals are located so as to have rotational symmetry, it is possible to achieve the same effect regardless of the location.

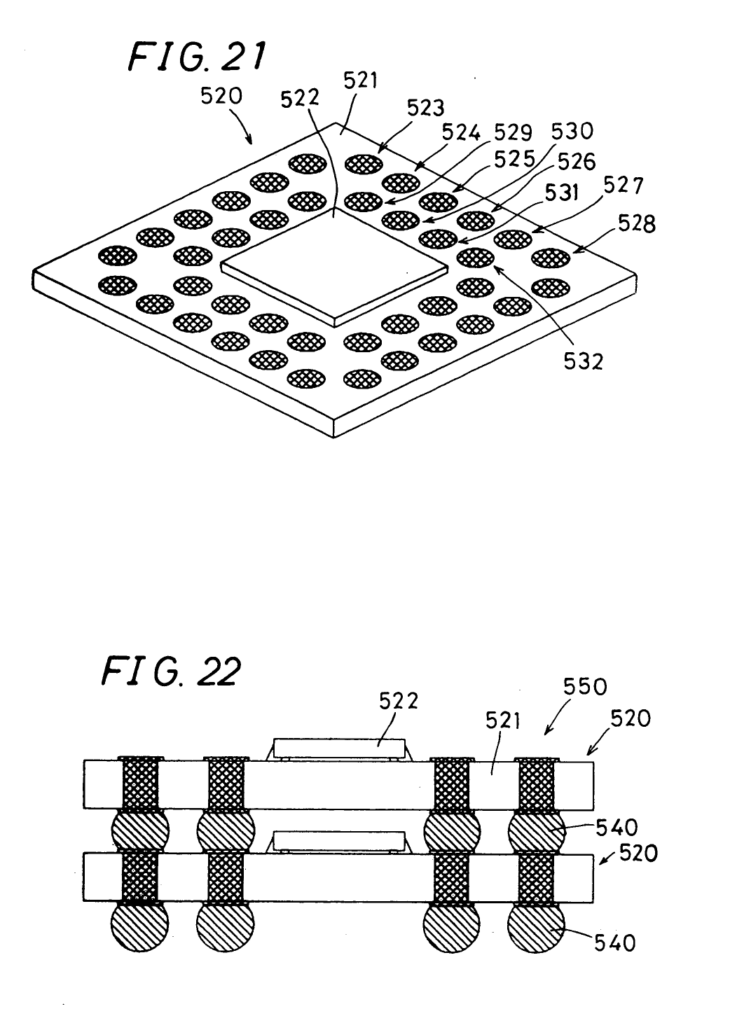

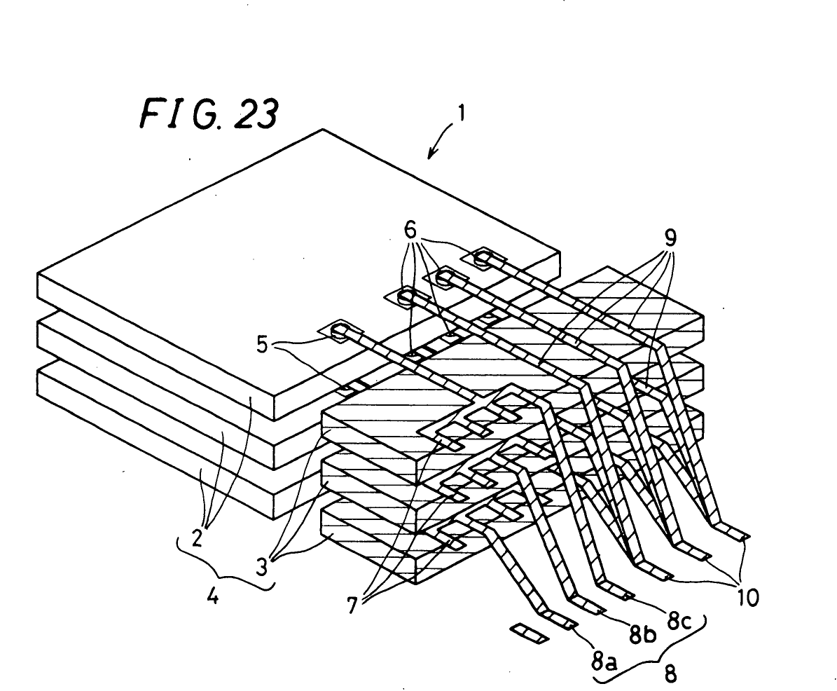

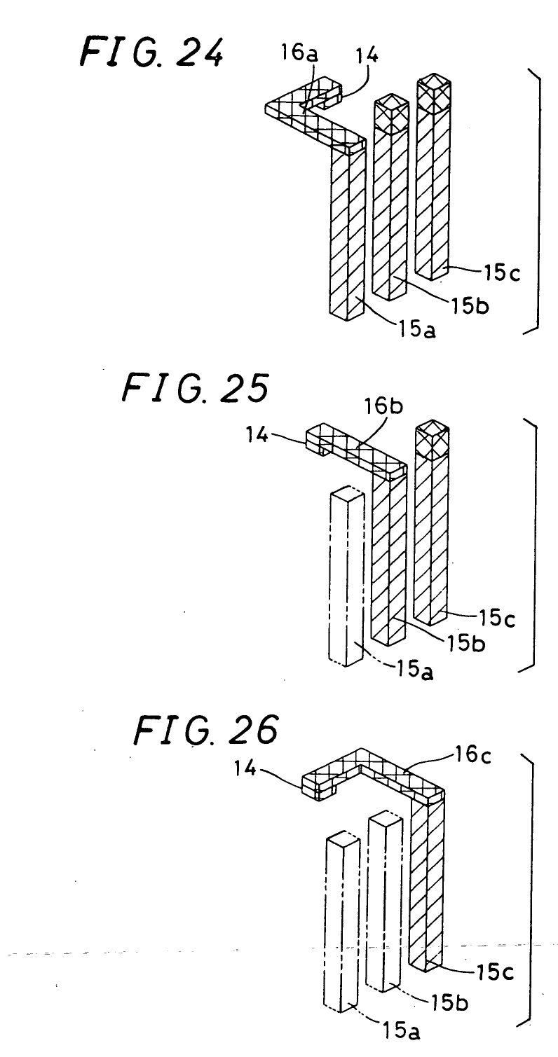

FIG. 21 is a perspective view showing a memory package 520 according to still another embodiment of the invention, and FIG. 22 is a cross section view showing a module with memory packages 550 stacked. In the present embodiment, the electronic component is the memory package 520. This memory package 520 is configured with a memory chip 522 mounted on a carrier 521, and the carrier 521 has a plurality of terminals classified into a plurality of terminal groups 523 to 532. The terminals of the terminal groups 523 to 532 are formed so as to have rotational symmetry of a predetermined fold-number (a natural number of 2 or more), or have rotational symmetry of a predetermined fold-number (a natural number multiple of 2) and plane symmetry with respect to a plane including a rotational symmetry axial line. These terminals are connected to the memory chip 522 by wires. Moreover, the terminals have connecting portions that pierce in the thickness direction on both the sides. By stacking these memory packages 520 so that the attitudes are shifted from each other as in the embodiments shown in FIGS. 1 to 20 and connecting the terminals to each other by using, for example, solder 540, it is possible to form the module 550. Such an electronic component can also achieve the same effect.

The aforementioned embodiments merely exemplify the invention, and the configurations thereof can be changed within the scope of the invention. For example, the electronic component may be a semiconductor chip other than a memory chip, for example, an LSI chip. Moreover, the terminal is not limited to the aforementioned terminal.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

### INDUSTRIAL APPLICABILITY

According to the invention, terminals of a common connection terminal group of an electronic component are formed so as to have rotational symmetry of a predetermined fold-number, and have connecting portions on both surfaces in the stacking direction of the electronic component. Moreover, terminals of an individual connection terminal group are formed so as to have rotational symmetry of the predetermined number of fold, one of the terminals, namely a specific terminal has a connecting portion on at least one of the surfaces in the stacking direction of the electronic component, and the rest of the terminals, namely, related terminals have connecting portions on both the surfaces in the stacking direction of the electronic component.

The electronic components with the terminals formed in a symmetric location in this manner, when stacked so as to be shifted from each other by an angle obtained by dividing 360 degrees by the number of fold, make it possible to assemble a module in which the terminals of the common electrode terminal groups are commonly connected to the component outside the module and the specific terminals of the individual connection terminal groups are individually connected to the component outside the module. Consequently, on assembling a module by stacking a plurality of electronic components, it is possible to use electronic components having the same configuration, without preparing electronic components having different configurations. Accordingly, it is possible to reduce time and effort to manufacture electronic components for assembling a module by stacking, and easily manufacture the electronic components.

Further, according to the invention, it is possible to easily form a module in which the number of layers is equal to or less than the predetermined fold-number.

Furthermore, according to the invention, the terminals of the common electrode terminal groups and the individual connection terminal groups have line symmetry with respect to a symmetry line that passes through the center of rotation symmetry, it is also possible to stack the electronic components in the inverted state with respect to the stacking direction, and it is possible even in this state to assemble a module in which the terminals of the common electrode terminal groups are commonly connected to the component outside the module and the specific terminals of the individual connection terminal groups are individually connected to the component outside the module. Accordingly, it is possible to easily form a module in which the number of layers is two or less times the predetermined fold-number.

Still further, according to the invention, by stacking the electronic component pairs formed so that the principal surfaces of the two electronic components are opposed, namely, one principal surfaces in the stacking direction of the electronic components are opposed to each other, in the shifted state from each other by an angle obtained by dividing 360 degrees by the predetermined fold-number, it is possible to easily form a module in which the number of layers is two or less times the predetermined fold-number.

Still further, according to the invention, the specific terminal has a connecting portion formed on only either of the surfaces in the stacking direction of the electronic component, so that it is possible to reduce a portion connected to the component outside the module. Consequently, it is possible to reduce a load on the module on driving the module from the component outside the module, and it is possible to contribute to making the module become high-speed and have a high level of function.

Still further, according to the invention, the external shape is a regular polygon that has the same number of angles as the predetermined fold-number, so that in the case of stacking the electronic components, it is possible to stack with the rim portions lined up. Consequently, it is possible to make an occupied space necessary to locate the module as small as possible.

Still further, according to the invention, the attitude information output terminal group is provided as one of the individual connection terminal groups, and by outputting information representing valid from the specific terminals in response to an output request from the component outside the module to the terminals while switching the related terminals of the attitude information output terminal groups, it is possible to give information on the positions of the specific terminals of the electronic components to the component outside the module. Consequently, it is possible to give information representing the attitudes of the electronic components to the component outside the module.

Still further, according to the invention, the internal circuit that sets an operation environment appropriate to a stacking state is provided, and the command input terminal group is provided as one of the common connection terminal groups. When a setting command is given from the component outside the module to the command input terminal group, an operation environment appropriate to a stacking state is set by the internal circuit. Consequently, it is possible to give a setting command and set an operation environment after stacking the plurality of electronic components and forming the module, and it is possible to assemble a highly convenient module that operates in a favorable manner.

Still further, according to the invention, the alignment marks used for positioning on stacking the electronic components are located so as to have the symmetry. Consequently, as far as the component outside the module has at least one alignment mark, it is possible to position the electronic components in positions shifted from each other by an angle obtained by dividing 360 degrees by the predetermined fold-number.

Still further, according to the invention, it is possible to obtain a favorable module by stacking the plurality of semiconductor devices.

Still further, according to the invention, by stacking the plurality of electronic components having the same configuration, a module is formed, and it is possible to easily obtain a favorable module.

Still further, according to the invention, the plurality of electronic components are stacked so that the attitudes are shifted from each other by an angle obtained by dividing 360 degrees by the predetermined fold-number about the center of rotational symmetry, and the connecting portions of the terminals of the electronic components adjacent to each other in the stacking direction are connected to each other. Consequently, it is possible to assemble a module in which the terminals of the common electrode terminal groups are commonly connected to the component outside the module and the specific terminals of the individual connection terminal groups are individually connected to the component outside the module. Such a module that allows high-density packaging can be assembled with ease.

Still further, according to the invention, the plurality of electronic components are stacked so that the attitudes are shifted from each other by an angle obtained by dividing 360 degrees by the predetermined fold-number about the center of rotational symmetry, and the connecting portions of the terminals of the electronic components adjacent to each other in the stacking direction are connected to each other. Consequently, it is possible to assemble a module in which the terminals of the common electrode terminal groups are commonly connected to the component outside the module and the specific terminals of the individual connection terminal groups are individually connected to the component outside the module. Such a module that allows high-density packaging can be assembled with ease.

Furthermore, the alignment marks having the same symmetry as symmetry of the terminals are formed on the electronic component, and it is possible to position the electronic components by using the alignment mark formed on the board. On this positioning, at least one alignment mark on the board is sufficient. The electronic component is formed more accurately than the board, and as to the alignment marks, the alignment marks on the electronic component are formed more accurately than the alignment mark on the board. By forming the alignment marks on the electronic component so as to have symmetry as described before, it is possible to position the electronic components by using the highly accurate alignment marks on the electronic component as much as possible, and it is possible to position the electronic components with high accuracy, so that it is possible to assemble a highly accurate module.

Still further, according to the invention, it is possible to assemble a favorable module by stacking the plurality of semiconductor devices.

Still further, according to the invention, an output request is given to the terminals of the attitude information terminal groups of a module assembled by stacking the plurality of electronic components having the attitude information terminal groups. Consequently, it is possible to obtain information representing valid from the specific terminals of the attitude information terminal groups of the electronic components, and it is possible to detect the positions of the specific terminals. Consequently, it is possible to detect the attitudes of the electronic components in the module, and it is possible to detect the alignment of the electronic components in the module. Accordingly, it is possible to identify the modules on the basis of the differences of the alignments.

Still further, according to the invention, it is possible to favorably identify a module assembled by stacking the plurality of semiconductor devices.

Still further, according to the invention, a setting command is given to the terminals of the command input terminal groups of a module assembled by stacking the plurality of electronic components having the command input terminal groups. When a setting command is given to the electronic components, operation environments are set in response to the setting command. Consequently, it is possible to set operation environments in the electronic components.

Still further, according to the invention, it is possible to set operation environments in the semiconductor devices of a module assembled by stacking the plurality of semiconductor devices, and it is possible to obtain a favorable module.

1. A semiconductor chip having an internal circuit, capable of being assembled into a module in the form of a stack of a plurality of layers, comprising:
a common connection terminal group; and
an individual connection terminal group,
wherein an internal circuit is formed on at least one principal surface of a semiconductor substrate, and conductive paths that reach an opposite surface from the principal surface are provided,
wherein terminals of the common connection terminal group and the individual connection terminal group are connected to the conductive paths,
wherein the common connection terminal group is located so as to have rotational symmetry of a predetermined fold-number, and the common connection terminal group has a plurality of terminals which are connected to the internal circuit, and terminals which are to be connected to a component outside the module in common with terminals of the other semiconductor chips of the stack, and connecting portions for connecting with the terminals of the common connection terminal groups of the other semiconductor chips are formed on both surfaces in the stacking direction of the semiconductor chips, and
wherein the individual connection terminal group is located so as to have rotational symmetry of the predetermined fold-number, and has a plurality of terminals including at least one specific terminal and related terminals, which specific terminal is connected to the internal circuit and is to be connected to a component outside the module independent from the specific terminals of the other semiconductor chips of the stack, and has a connecting portion for connecting with the terminals of the individual connection terminal groups of the other semiconductor chips of the stack, formed on at least one surface of the surfaces in the stacking direction of the semiconductor chip, and which related terminals are disposed in relation to the specific terminals of the other semiconductor chips of the stack, and have connecting portions for connecting with the terminals of the individual connection terminal groups of the other semiconductor chips, formed on both surfaces in the stacking direction of the semiconductor chip.

2. The semiconductor chip of claim 1, wherein on stacking the plurality of semiconductor chips, the semiconductor chips are stacked so that one surfaces of the respective semiconductor chips are all directed to one direction.

3. The semiconductor chip of claim 1, wherein
the terminals of the common electrode terminal groups and the individual connection terminal groups are located so as to have not only rotational symmetry of the predetermined fold-number but also line symmetry with respect to a symmetry line that passes through a center of rotation symmetry, and
on stacking the plurality of semiconductor chips, at least one of the semiconductor chips is stacked so that one surface of the at least one semiconductor chip is directed to one direction, and the remaining semiconductor chips are stacked so that the other surfaces of the respective semiconductor chips are directed to the one direction.

4. The semiconductor chip of claim 3, wherein, on stacking the plurality of semiconductor chips, principal surfaces of two of the semiconductor chips are opposed to each other, and the plurality of opposed semiconductor chip pairs are stacked further.

5. The semiconductor chip of claim 1, wherein the specific terminal has the connecting portion for connecting with the terminals of individual connection terminal groups of the other semiconductor chips, formed on only one surface of the surfaces in the stacking direction thereof.

6. The semiconductor chip of claim 1, wherein the external shape is a regular polygon that has the same number of angles as that of the predetermined fold-number.

7. The semiconductor chip of claim 1, wherein the individual connection terminal groups include an attitude information output terminal group in which the specific terminal is connected to an internal circuit that outputs information representing valid in response to an output request from the component outside the module, and the related terminals are connected to an internal circuit that, in response to an output request from the component outside the module, is switched between a state of outputting information representing invalid that takes priority to information representing valid in the component outside the module, and a state of noninterfering with the related terminals.

8. The semiconductor chip of claim 1, wherein
each of the semiconductor chips has an internal circuit that sets an operation environment appropriate to a stacking state of each of the semiconductor chips based on a setting command given from the component outside the module, and
the common connection terminal groups include a command input terminal group provided with command input terminals to which a setting command as a command for setting an operation environment appropriate to a stacking state in each of the semiconductor chips is given from the component outside the module.

9. The semiconductor chip of claim 1, wherein alignment marks used for positioning on stacking the semiconductor chips are located so as to have the same symmetry as that of the terminals.

10. (canceled)

11. A module formed with the plurality of semiconductor chips of claim 1 stacked.

12. A method of assembling a module by stacking the plurality of semiconductor chips of claim 1, comprising:
stacking the semiconductor chips so that attitudes thereof are shifted from each other by an angle obtained by dividing 360 degrees by the predetermined fold-number about the center of rotational symmetry; and
connecting the connecting portions of the terminals of the semiconductor chips adjacent to each other in the stacking direction, to each other.

13. A method of assembling a module by stacking the plurality of semiconductor chips of claim 9 on a board, comprising:
stacking the semiconductor chips so that attitudes thereof are shifted from each other by an angle obtained by dividing 360 degrees by the predetermined fold-number about the center of rotational symmetry based on positional relation between an alignment mark formed on the board and the alignment marks formed on the semiconductor chips; and
connecting the connecting portions of the terminals of the semiconductor chips adjacent to each other in the stacking direction, to each other.

14. (canceled)

15. A method of identifying a module assembled by stacking the plurality of semiconductor chips of claim 7 so that attitudes thereof are shifted from each other by an angle obtained by dividing 360 degrees by the predetermined fold-number about the center of rotational symmetry and connecting the connecting portions of the terminals of the semiconductor chips adjacent to each other in the stacking direction, to each other, comprising:
by giving an output request to the terminals of the attitude information terminal groups of the semiconductor chips, based on outputted information representing valid and information representing invalid, detecting the positions of the specific terminals of the attitude information terminal groups in the semiconductor chips and detecting attitudes of the semiconductor chips, and identifying a module based on stacking states of the semiconductor chips.

16. (canceled)

17. A method of setting an operation environment of a module assembled by stacking the plurality of semiconductor chips of claim 8 so that attitudes thereof are shifted from each other by an angle obtained by dividing 360 degrees by the predetermined fold-number about the center of rotational symmetry and connecting the connecting portions of the terminals of the semiconductor chips adjacent to each other in the stacking direction, to each other, comprising:
giving a setting command to the command input terminal groups and setting operation environments appropriate to stacking states in the semiconductor chips.

18. (canceled)
